(19) United States
(12) Patent Application Publication
(10) Pub. No.: US 2024/0407166 A1
(43) Pub. Date: Dec. 5, 2024

(54) THREE-DIMENSIONAL MEMORY DEVICES INCLUDING SELF-ALIGNED SOURCE-CHANNEL JUNCTIONS AND METHODS FOR FORMING THE SAME

(71) Applicant: WESTERN DIGITAL TECHNOLOGIES, INC.,, SAN JOSE, CA (US)

(72) Inventors: Kento ISERI, Yokkaichi (JP); Takaaki IWAI, Yokkaichi (JP); Naoto NORIZUKI, Yokkaichi (JP)

(21) Appl. No.: 18/479,457

(22) Filed: Oct. 2, 2023

Related U.S. Application Data
(63) Continuation-in-part of application No. 18/450,095, filed on Aug. 15, 2023.
(60) Provisional application No. 63/504,915, filed on May 30, 2023.

(51) Int. Cl. H10B 43/27; G11C 16/04; H10B 41/10; H10B 41/27; H10B 41/35; H10B 43/10; H10B 43/35

(52) U.S. Cl. CPC H10B 43/27; G11C 16/0483; H10B 41/10; H10B 41/27; H10B 41/35; H10B 43/10; H10B 43/35

(57) ABSTRACT

A semiconductor structure includes an alternating stack of insulating layers and electrically conductive layers, a memory opening vertically extending through the alternating stack, a memory opening fill structure located in the memory opening and including a memory film, a vertical semiconductor channel, and a semiconductor source cap structure which is at least partially laterally surrounded by the memory film and which contacts the vertical semiconductor channel, and a source layer contacting at least a first end surface segment of the semiconductor source cap structure.

### FIELD

The present disclosure relates generally to the field of semiconductor devices, and particularly to three-dimensional memory devices including self-aligned source-channel junctions and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure includes an alternating stack of insulating layers and electrically conductive layers, a memory opening vertically extending through the alternating stack, a memory opening fill structure located in the memory opening and including a memory film, a vertical semiconductor channel, and a semiconductor source cap structure which is at least partially laterally surrounded by the memory film and which contacts the vertical semiconductor channel, and a source layer contacting at least a first end surface segment of the semiconductor source cap structure.

According to another aspect of the present disclosure, a method of forming a semiconductor structure comprises: forming a source-side spacer layer over a carrier substrate; forming an alternating stack of insulating layers and spacer material layers over the source-side spacer layer, wherein the spacer material layers are formed as, or are subsequently replaced with, electrically conductive layers; forming a memory opening through the alternating stack and the source-side spacer layer; forming a memory film at a peripheral portion of the memory opening; forming a source cap structure at a bottom portion of the memory film; forming a vertical semiconductor channel on a top surface of the source cap structure and on an inner sidewall of the memory film; removing the carrier substrate; and forming a source layer on an exposed bottom surface segment of the source cap structure.

### BRIEF DESCRIPTION OF THE DRAWINGS

FIG. 1 is a schematic vertical cross-sectional view of a first exemplary structure after formation of a backside stopper layer and a source-side spacer layer over a carrier substrate according to a first embodiment of the present disclosure.

FIG. 2 is a schematic vertical cross-sectional view of the first exemplary structure after formation of a first-tier alternating stack of first insulating layers and first sacrificial material layers according to the first embodiment of the present disclosure.

FIG. 3 is a schematic vertical cross-sectional view of the first exemplary structure after formation of first stepped surfaces and a first stepped dielectric material portion according to the first embodiment of the present disclosure.

FIG. 4 is a schematic vertical cross-sectional view of the first exemplary structure after formation of first-tier openings according to the first embodiment of the present disclosure.

FIG. 5 is a vertical cross-sectional view of the first exemplary structure after formation of sacrificial opening fill structures according to the first embodiment of the present disclosure.

FIG. 6 is a vertical cross-sectional view of the first exemplary structure after formation of a second-tier alternating stack of second insulating layers and second sacrificial material layers, second stepped surfaces, and a second stepped dielectric material portion according to the first embodiment of the present disclosure.

FIG. 7 is a vertical cross-sectional view of the first exemplary structure after formation of second-tier openings according to the first embodiment of the present disclosure.

FIG. 8A is a schematic vertical cross-sectional view of the first exemplary structure after formation of inter-tier memory openings and inter-tier support openings according to the first embodiment of the present disclosure.

FIG. 8B is a top-down view of the first exemplary structure of FIG. 8A. The vertical plane A-A is the cut plane of the vertical cross-sectional view of FIG. 8A.

FIGS. 9A-9G are sequential vertical cross-sectional views of a memory opening during formation of a memory opening fill structure in the first exemplary structure according to the first embodiment of the present disclosure.

FIG. 10A is a schematic vertical cross-sectional view of the first exemplary structure after formation of memory opening fill structures according to the first embodiment of the present disclosure.

FIG. 10B is a top-down view of the first exemplary structure of FIG. 10A. The vertical plane A-A is the cut plane of the vertical cross-sectional view of FIG. 10A.

FIG. 11A is a vertical cross-sectional view of the first exemplary structure after formation of lateral isolation trenches according to the first embodiment of the present disclosure.

FIG. 11B is a top-down view of the first exemplary structure of FIG. 11A. The vertical plane A-A is the cut plane of the vertical cross-sectional view of FIG. 11A.

FIG. 12 is a vertical cross-sectional view of the first exemplary structure after formation of laterally-extending cavities according to the first embodiment of the present disclosure.

FIG. 13 is a schematic vertical cross-sectional view of the first exemplary structure after formation of electrically conductive layers according to the first embodiment of the present disclosure.

FIG. 14A is a vertical cross-sectional view of the first exemplary structure after formation of lateral isolation trench fill structures, layer contact via structures, and drain contact via structures according to the first embodiment of the present disclosure.

FIG. 14B is a top-down view of the first exemplary structure of FIG. 14A. The vertical plane A-A is the cut plane of the vertical cross-sectional view of FIG. 14A.

FIG. 15 is a vertical cross-sectional view of the first exemplary structure after formation of a memory die according to the first embodiment of the present disclosure.

FIG. 16 is a vertical cross-sectional view of a logic die according to the first embodiment of the present disclosure.

FIG. 17 is a vertical cross-sectional view of the first exemplary structure after attaching the logic die to the memory die according to the first embodiment of the present disclosure.

FIG. 18 is a vertical cross-sectional view of the first exemplary structure after removal of the carrier substrate according to the first embodiment of the present disclosure.

FIG. 19A is a vertical cross-sectional view of the first exemplary structure after removal of the backside stopper layer and end portions of the memory films according to the first embodiment of the present disclosure.

FIG. 19B is a magnified view of a region of the first exemplary structure of FIG. 19A.

FIG. 20A is a vertical cross-sectional view of the first exemplary structure after formation of a source layer according to the first embodiment of the present disclosure.

FIG. 20B is a magnified view of a region of the first exemplary structure of FIG. 20A.

FIG. 21 is a schematic vertical cross-sectional view of a second exemplary structure after formation of discrete source-level openings according to a second embodiment of the present disclosure.

FIG. 22 is a schematic vertical cross-sectional view of the second exemplary structure after formation of annular recess cavity cavities around the discrete source-level openings according to the second embodiment of the present disclosure.

FIG. 23 is a schematic vertical cross-sectional view of the second exemplary structure after formation of sacrificial pedestal structures according to the second embodiment of the present disclosure.

FIG. 24 is a schematic vertical cross-sectional view of the second exemplary structure after formation of a first-tier alternating stack of first insulating layers and first sacrificial material layers, first stepped surfaces, and a first stepped dielectric material portion according to the second embodiment of the present disclosure.

FIG. 25 is a schematic vertical cross-sectional view of the second exemplary structure after formation of first-tier openings according to the second embodiment of the present disclosure.

FIG. 26 is a vertical cross-sectional view of the second exemplary structure after formation of sacrificial opening fill structures according to the second embodiment of the present disclosure.

FIG. 27 is a vertical cross-sectional view of the second exemplary structure after formation of a second-tier alternating stack of second insulating layers and second sacrificial material layers, second stepped surfaces, a second stepped dielectric material portion according to the second embodiment of the present disclosure.

FIG. 28 is a vertical cross-sectional view of the second exemplary structure after formation of second-tier openings according to the second embodiment of the present disclosure.

FIG. 29A is a schematic vertical cross-sectional view of the second exemplary structure after formation of support pillar structures according to the second embodiment of the present disclosure.

FIG. 29B is a schematic vertical cross-sectional view of the second exemplary structure after formation of inter-tier memory openings according to the second embodiment of the present disclosure.

FIGS. 30A-30G are sequential vertical cross-sectional views of a memory opening during formation of a memory opening fill structure in the second exemplary structure according to the second embodiment of the present disclosure.

FIG. 31A is a schematic vertical cross-sectional view of the second exemplary structure after formation of memory opening fill structures according to the second embodiment of the present disclosure.

FIG. 31B is a top-down view of the second exemplary structure of FIG. 31A. The vertical plane A-A is the cut plane of the vertical cross-sectional view of FIG. 31A.

FIG. 32A is a vertical cross-sectional view of the second exemplary structure after formation of lateral isolation trenches according to the second embodiment of the present disclosure.

FIG. 32B is a top-down view of the second exemplary structure of FIG. 32A. The vertical plane A-A is the cut plane of the vertical cross-sectional view of FIG. 32A.

FIG. 33 is a vertical cross-sectional view of the second exemplary structure after formation of laterally-extending cavities according to the second embodiment of the present disclosure.

FIG. 34 is a schematic vertical cross-sectional view of the second exemplary structure after formation of electrically conductive layers according to the second embodiment of the present disclosure.

FIG. 35A is a vertical cross-sectional view of the second exemplary structure after formation of lateral isolation trench fill structures, layer contact via structures, and drain contact via structures according to the second embodiment of the present disclosure.

FIG. 35B is a top-down view of the second exemplary structure of FIG. 35A. The vertical plane A-A is the cut plane of the vertical cross-sectional view of FIG. 35A.

FIG. 36 is a vertical cross-sectional view of the second exemplary structure after formation of a memory die according to the second embodiment of the present disclosure.

FIG. 37 is a vertical cross-sectional view of the second exemplary structure after attaching the logic die to the memory die according to the second embodiment of the present disclosure.

FIG. 38 is a vertical cross-sectional view of the second exemplary structure after removal of the carrier substrate according to the second embodiment of the present disclosure.

FIG. 39A is a vertical cross-sectional view of the second exemplary structure after removal of the backside stopper layer and end portions of the memory films according to the second embodiment of the present disclosure.

FIG. 39B is a magnified view of a region of the second exemplary structure of FIG. 39A.

FIG. 40A is a vertical cross-sectional view of the second exemplary structure after formation of a source layer according to the second embodiment of the present disclosure.

FIG. 40B is a magnified view of a region of the second exemplary structure of FIG. 40A.

FIG. 40C is a magnified view of a region of a first alternative configuration of the second exemplary structure.

FIG. 40D is a magnified view of a region of a second alternative configuration of the second exemplary structure.

### DETAILED DESCRIPTION

As discussed above, the embodiments of the present disclosure are directed to a three-dimensional memory device containing self-aligned channel cap structures and methods for forming the same, the various aspects of which are described below. Embodiments of the disclosure can be employed to form various structures including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many a number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

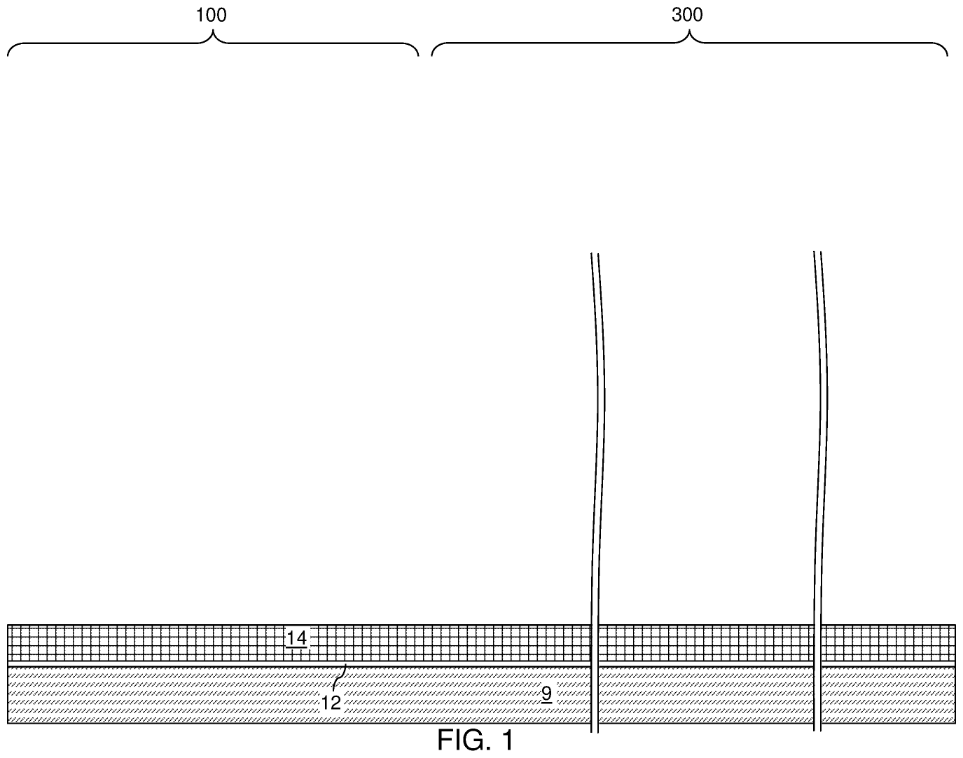

Referring to FIG. 1, a first exemplary structure according to a first embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers and dielectric material portions to be subsequently formed. In case the carrier substrate 9 comprise silicon (e.g., a single crystal silicon wafer), at least a top surface portion of the carrier substrate 9 may be doped with boron to act as an etch stop and to prevent collateral etching during a subsequent etching step. As used herein, an etch process etches a first material selective to a second material if the etch rate of the etch process for the first material is at least three times the etch rate for the second material. The atomic concentration of boron in at least the boron-doped portion of the carrier substrate 9 (or in the entire carrier substrate) may be at least 1×10¹⁹/cm³, such as in a range from 5×10¹⁹/cm³ to 2×10²¹/cm³, such as from 1×10²⁰/cm³ to 1×10²¹/cm³, although lesser and greater thicknesses may also be employed.

A backside stopper layer 12 can be formed on the top surface of the carrier substrate 9. The backside stopper layer 12 comprises an insulating material, such as silicon oxide, and may have a thickness in a range from 10 nm to 200 nm, such as from 20 nm to 100 nm, although lesser and greater thicknesses may also be employed. The backside stopper layer 12 may be deposited on the carrier substrate 9 by chemical vapor deposition, atomic layer deposition or sputtering. Alternatively, if the carrier substrate 9 comprises a silicon substrate, then the backside stopper layer 12 may be formed by oxidizing an upper surface of the carrier substrate 9.

A source-side spacer layer 14 can be formed over the backside stopper layer 12. The source-side spacer layer 14 has a uniform thickness, which may be in range from 50 nm to 1,000 nm, such as from 100 nm to 500 nm, although lesser and greater thicknesses may also be employed. The source-side spacer layer 14 may comprise a semiconductor material, a conductive material, or an insulating material. Generally, the source-side spacer layer 14 comprises a material that is different from the materials of an alternating stack of insulating layers and spacer material layers (such as sacrificial material layers) to be subsequently formed. Further, the source-side spacer layer 14 comprises a material providing a greater etch resistance than the materials of the alternating stack during an anisotropic etch process to be subsequently employed to form openings through the alternating stack.

In one embodiment, the source-side spacer layer 14 comprises and/or consists essentially of a semiconductor material, which may be an elemental semiconductor material such as silicon (e.g., polysilicon) or germanium, or a compound semiconductor material such as silicon-germanium or a III-V compound semiconductor material. In one embodiment, vertical semiconductor channels to be subsequently formed comprises dopants of a first conductivity type (which may be p-type or n-type), and the source-side spacer layer 14 comprises doped semiconductor material having a doping of a second conductivity type that is the opposite of the first conductivity type. In one embodiment, the atomic concentration of electrical dopants of the second conductivity type in the source-side spacer layer 14 may in a range from 1×10¹⁶/cm³ to 1×10²⁰/cm³, such as from 1×10¹⁸/cm³ to 5×10¹⁹/cm³.

The first exemplary structure comprises a memory array region 100 in which a three-dimensional array of memory elements is subsequently formed, and a contact region 300 in which layer contact via structures are formed, which contact word lines embodied as electrically conductive layers.

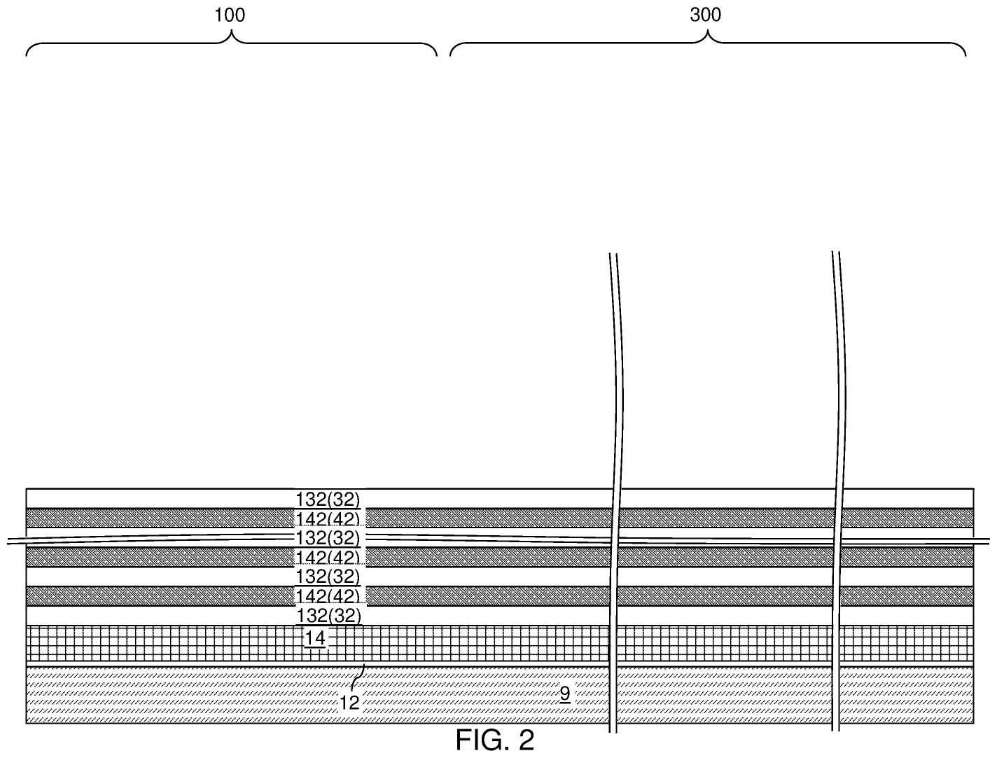

Referring to FIG. 2, a first alternating stack of insulating layers 32 and spacer material layers can be formed over the carrier substrate 9. The spacer material layers may be formed as sacrificial material layers 42. In case a second alternating stack of additional insulating layers and additional spacer material layers is subsequently formed over the first alternating stack to form a multi-tier structure, the first alternating stack is referred to as a first-tier alternating stack, and the second alternating stack is referred to as a second-tier alternating stack. In this case, the insulating layers 32 within the first-tier alternating stack are herein referred to as first insulating layers 132, and spacer material layers (such as the sacrificial material layers 42) within the first-tier alternating stack are herein referred to as first spacer material layers (such as first sacrificial material layers 142). In one embodiment, the first spacer material layers may comprise first sacrificial material layers 142. In this case, a first-tier alternating stack (132, 142) of first insulating layers 132 and first sacrificial material layers 142 can be formed over the source-side spacer layer 14.

The first insulating layers 132 comprise an insulating material such as undoped silicate glass or a doped silicate glass, and the first sacrificial material layers 142 comprise a sacrificial material such as silicon nitride or a silicon-germanium alloy. In one embodiment, the first insulating layers 132 may comprise silicon oxide layers, and the first sacrificial material layers 142 may comprise silicon nitride layers. The first-tier alternating stack (132, 142) may comprise multiple repetitions of a unit layer stack including a first insulating layer 132 and a first sacrificial material layer 142. The total number of repetitions of the unit layer stack within the first-tier alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. The first exemplary structure comprises a memory array region 100 in which a three-dimensional array of memory elements is to be subsequently formed, and a contact region 300 in which layer contact via structures contacting word lines are to be subsequently formed.

While an embodiment is described in which the first spacer material layers are formed as first sacrificial material layers 142, the first spacer material layers may be formed as first electrically conductive layers in an alternative embodiment. In this case, processing steps performed to replace the first sacrificial material layers 142 with first electrically conductive layers may be omitted. Generally, spacer material layers of the present disclosure may be formed as, or may be subsequently replaced with, electrically conductive layers.

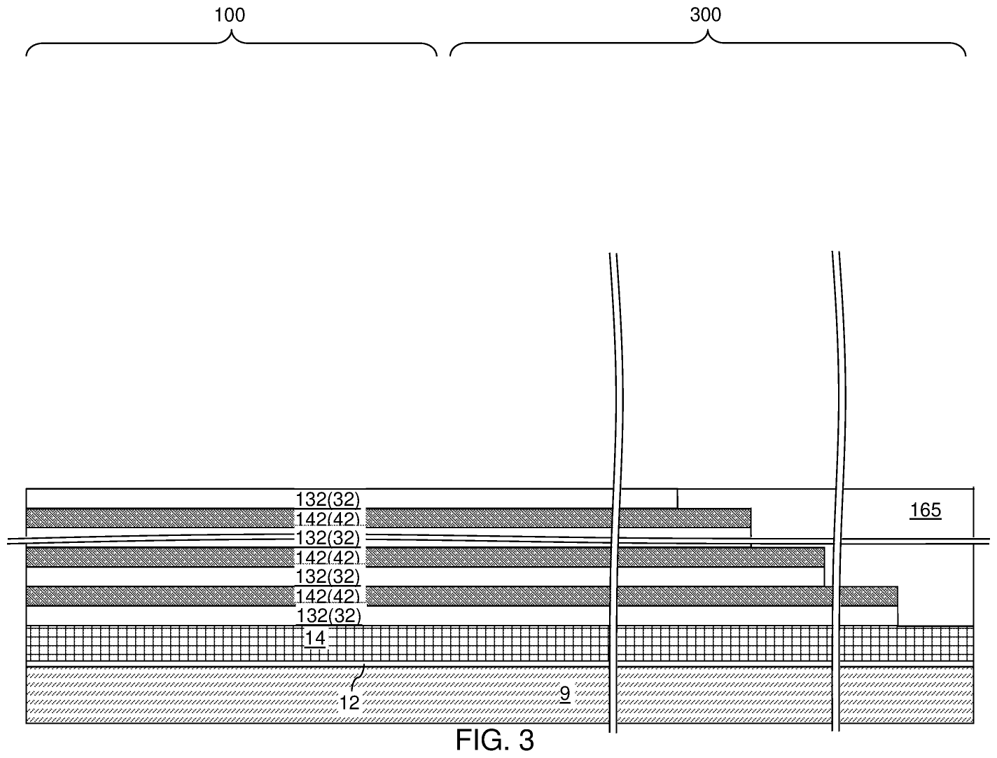

Referring to FIG. 3, first stepped surfaces can be formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first-tier alternating stack (132, 142) are removed through formation of the stepped surfaces. A “stepped cavity” refers to a cavity having stepped surfaces.

The first stepped cavity can have various stepped surfaces such that the horizontal cross-sectional shape of the first stepped cavity changes in steps as a function of the vertical distance from the top surface of the carrier substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

The first stepped surfaces of the first-tier alternating stack (132, 142) continuously extend from a bottommost layer within the first-tier alternating stack (132, 142) to a topmost layer within the first-tier alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the stepped cavity. Excess portions of the deposited dielectric material can be removed from above the top surface of the topmost layer of the first-tier alternating stack (132, 142), for example, by chemical mechanical planarization (CMP). The remaining portion of the deposited dielectric material filling the first stepped cavity constitutes the first stepped dielectric material portion 165. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F.

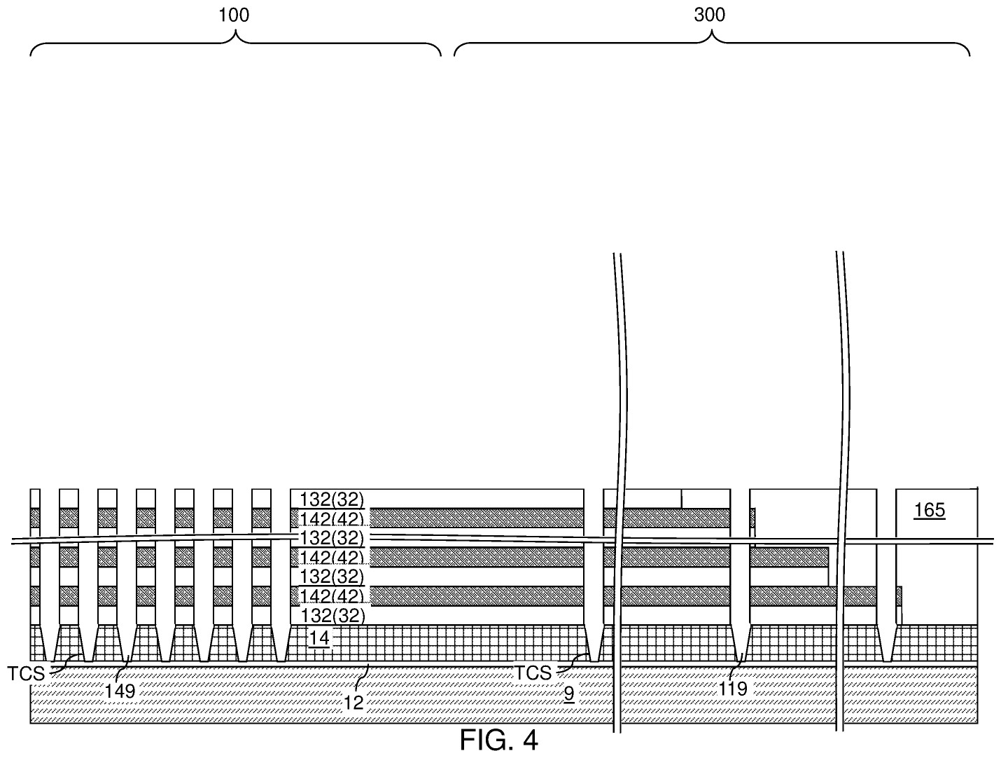

Referring to FIG. 4, a first etch mask layer (such as a photoresist layer) can be formed over the first-tier alternating stack (132, 142), and can be lithographically patterned to form openings therein. A first anisotropic etch process can be performed to transfer the pattern of the openings in the first etch mask layer through the first stepped dielectric material portion 165, the first-tier alternating stack (132, 142), and the source-side spacer layer 14. The first anisotropic etch process may comprise a first etch step having a first anisotropic etch chemistry that etches the materials of the first stepped dielectric material portion 165 and the first-tier alternating stack (132, 142) while forming vertical or substantially vertical sidewalls. The first anisotropic etch chemistry may be selective to the material of the source-side spacer layer 14, i.e., may etch the materials of the first stepped dielectric material portion 165 and the first-tier alternating stack (132, 142) at a significantly higher etch rate than the material of the source-side spacer layer 14. The source-side spacer layer 14 may be employed as an etch stop structure for the first etch step of the first anisotropic etch process.

Further, the first anisotropic etch process may comprise a second etch step having a second anisotropic etch chemistry that etches the material of the source-side spacer layer 14 while forming tapered sidewalls around voids formed by removal of the material of the source-side spacer layer 14. In one embodiment, the backside stopper layer 12 may be employed as an etch stop layer for the second etch step of the first anisotropic etch process.

First-tier memory openings 149 can be formed through the first-tier alternating stack (132, 142) and the source-side spacer layer 14 in the memory array region 100, and first-tier support openings 119 can be formed through the first stepped dielectric material portion 165, the first-tier alternating stack (132, 142), and the source-side spacer layer 14 in the contact region 300. Each of the first-tier memory openings 149 and the first-tier support openings 119 can have a respective bottom surface that is formed on the top surface of the backside stopper layer 12 or slightly below the top surface of the backside stopper layer 12. The first-tier memory openings 149 and the first-tier support openings 119 may have a diameter in a range from 40 nm too 400 nm, such as from 80 nm to 200 nm, although lesser and greater thicknesses may be employed. The first etch mask layer can be removed, for example, by ashing after the first anisotropic etch process.

In one embodiment, each of the first-tier memory openings 149 and the first-tier support openings 119 may comprise a respective top cavity portion having a cylindrical shape, and a respective bottom cavity portion having a shape of an inverted cone or an inverted conical frustum. As used herein, an inverted cone refers to a cone having an apex at a bottommost point. As used herein, an inverted conical frustum refers to a conical frustum having a variable lateral extent that increases with a vertical distance upward. An inverted conical frustum can be derived from an inverted cone by removing a bottommost portion of the inverted cone. Each bottom cavity portion of the first-tier memory openings 149 and the first-tier support openings 119 comprises a respective tapered conical sidewall TCS. The taper angle of the tapered conical sidewalls TCS relative to the vertical direction may be in a range from 3 degrees to 30 degrees, such as from 5 degrees to 15 degrees, although lesser and greater angles may also be employed. Thus, the source-side spacer layer 14 comprises openings that are defined by the tapered conical sidewalls TCS. The lateral extent of each opening in the source-side spacer layer 14 increases with a vertical distance from a horizontal plane including an interface between the source-side spacer layer 14 and the backside stopper layer 12 toward the first-tier alternating stack (132, 142).

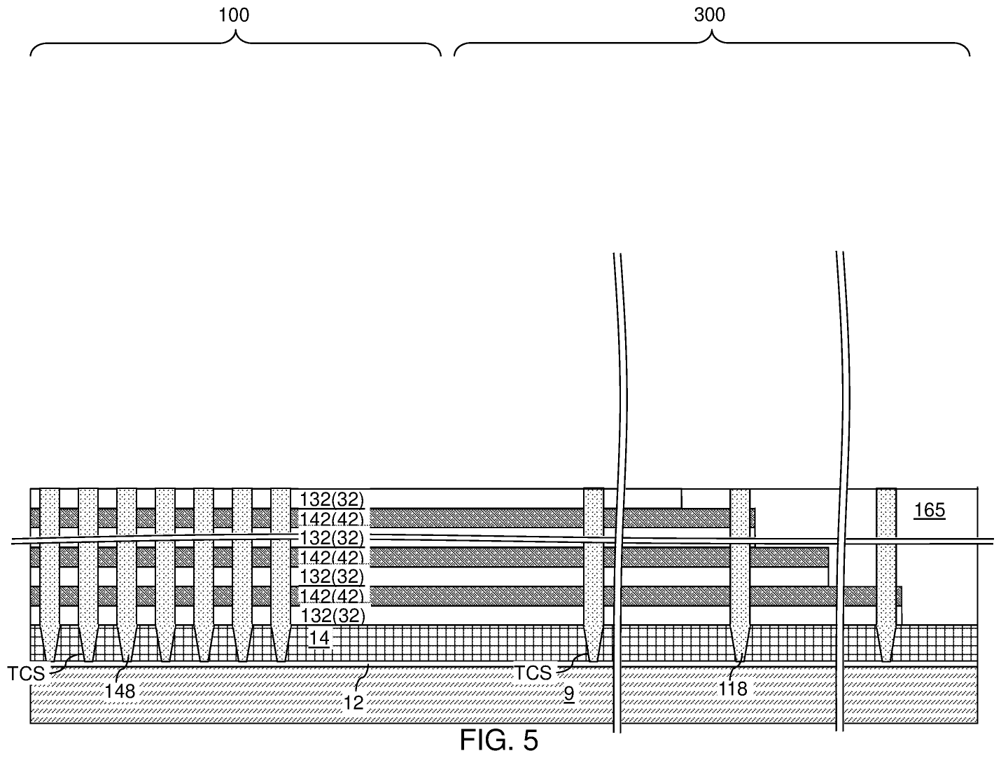

Referring to FIG. 5, a sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the first-tier memory openings 149 and in the first-tier support openings 119 by a conformal deposition process. Excess portions of the sacrificial fill material can be removed from above the top surface of the first-tier alternating stack (132, 142), for example, by a recess etch process. Each remaining portion of the sacrificial fill material that fills a respective first-tier memory opening 149 constitutes a sacrificial memory opening fill structure 148. Each remaining portion of the sacrificial fill material that fills a respective first-tier support opening 119 constitutes a sacrificial support opening fill structure 118. In one embodiment, each of the sacrificial memory opening fill structures 148 and the sacrificial support opening fill structures 118 comprises a respective upper cylindrical portion and a respective lower portion having a shape of an inverted cone or an inverted conical frustum.

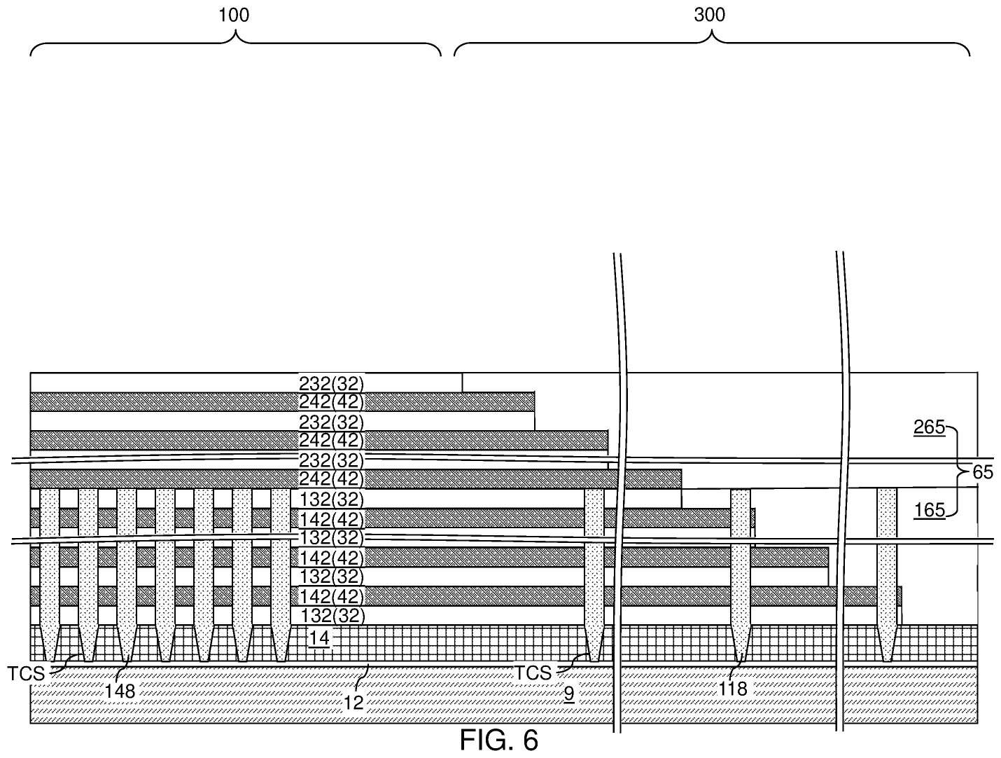

Referring to FIG. 6, a second-tier alternating stack (232, 242) of second insulating layers 232 and second spacer material layers may be formed above the first-tier alternating stack (132, 142) and the first stepped dielectric material portion 165. The second insulating layers 232 can be additional insulating layers 32 having a same material composition and a same thickness range as the first insulating layers 132. The second spacer material layers can be additional spacer material layers having a same material composition and a same thickness range as the first spacer material layers in the first-tier alternating stack (132, 142). In one embodiment, the second spacer material layers may comprise second sacrificial material layers 242. In this case, the second sacrificial material layers 242 can be additional sacrificial material layers 42 having a same material composition and a same thickness range as the first sacrificial material layers 142. The first insulating layers 132 and the second insulating layers 232 are collectively referred to as insulating layers 32. The first sacrificial material layers 142 and the second sacrificial material layers 242 are collectively referred to as sacrificial material layers 42.

The second-tier alternating stack (232, 242) may comprise multiple repetitions of a unit layer stack including a second insulating layer 232 and a second sacrificial material layer 242. The total number of repetitions of the unit layer stack within the second-tier alternating stack (232, 242) may be, for example, in a range from 8 to 1,024, such as from 32 to 256, although lesser and greater number of repetitions may also be employed. Each of the second insulating layers 232 may have a thickness in a range from 20 nm to 100 nm, such as from 30 nm to 60 nm, although lesser and greater thicknesses may also be employed. Each of the second sacrificial material layers 242 may have a thickness in a range from 20 nm to 100 nm, such as from 30 nm to 60 nm, although lesser and greater thicknesses may also be employed.

While an embodiment is described in which the second spacer material layers are formed as second sacrificial material layers 242, the second spacer material layers may be formed as second electrically conductive layers in an alternative embodiment. In this case, processing steps performed to replace the second sacrificial material layers 242 with second electrically conductive layers may be omitted. Generally, spacer material layers of the present disclosure may be formed as, or may be subsequently replaced with, electrically conductive layers.

Optional stepped surfaces are formed in the contact region 300 by patterning the second-tier alternating stack (232, 242). The stepped surfaces of the second-tier alternating stack (232, 242) may be laterally offset toward the memory array region 100 relative to the stepped surfaces of the first-tier alternating stack (132, 142) in a plan view. A second stepped cavity is formed within the volume from which portions of the second-tier alternating stack (232, 242) are removed through formation of the stepped surfaces. A “stepped cavity” refers to a cavity having stepped surfaces. The second stepped cavity can have various stepped surfaces such that the horizontal cross-sectional shape of the second stepped cavity changes in steps as a function of the vertical distance from the top surface of the carrier substrate 9. In one embodiment, the second stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type.

The stepped surfaces of the second-tier alternating stack (232, 242) continuously extend from a bottommost layer within the second-tier alternating stack (232, 242) to a topmost layer within the second-tier alternating stack (232, 242).

A second stepped dielectric material portion 265 (i.e., an insulating fill material portion) can be formed in the second stepped cavity by deposition of a dielectric material therein. For example, a dielectric material such as silicon oxide can be deposited in the stepped cavity. Excess portions of the deposited dielectric material can be removed from above the top surface of the topmost layer of the second-tier alternating stack (232, 242), for example, by chemical mechanical planarization (CMP). The remaining portion of the deposited dielectric material filling the second stepped cavity constitutes the second stepped dielectric material portion 265. If silicon oxide is employed for the second stepped dielectric material portion 265, the silicon oxide of the second stepped dielectric material portion 265 may, or may not, be doped with dopants such as B, P, and/or F. The combination of the first stepped dielectric material portion 165 and the second stepped dielectric material portion 265 may be collectively referred to as a stepped dielectric material portion 65.

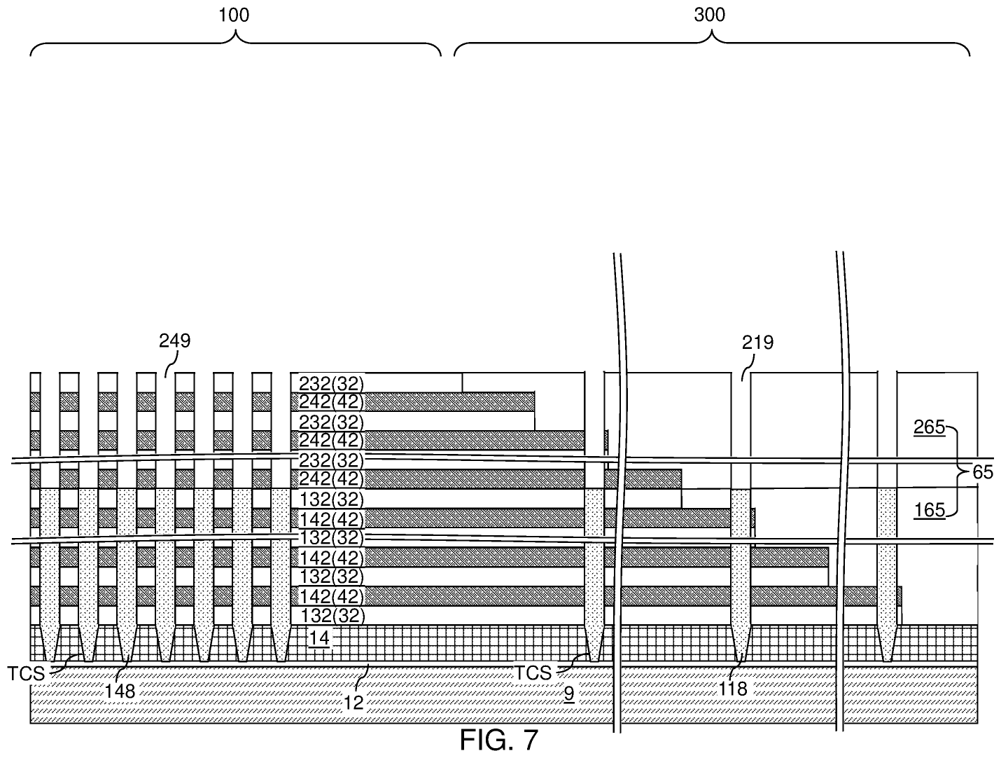

Referring to FIG. 7, a second etch mask layer (such as a photoresist layer) can be formed over the second-tier alternating stack (232, 242), and can be lithographically patterned to form openings therein. The pattern of the openings in the second etch mask layer may be the same as the pattern of the sacrificial opening fill structures (148, 118). A second anisotropic etch process can be performed to transfer the pattern of the openings in the second etch mask layer through the second stepped dielectric material portion 265 and the second-tier alternating stack (232, 242). Second-tier memory openings 249 can be formed through the second-tier alternating stack (232, 242) directly on a top surface of a respective sacrificial memory opening fill structure 148 in the memory array region 100. Second-tier support openings 219 can be formed through the second stepped dielectric material portion 165 and the second-tier alternating stack (232, 242) directly on a top surface of a respective sacrificial support opening fill structure 118 in the contact region 300.

Each of the second-tier memory openings 249 and the second-tier support openings 219 may have about the same diameter as the diameter of a respective underlying sacrificial opening fill structure (148, 118). Ideally, the second-tier memory openings 249 have a 100% areal overlap with the sacrificial memory opening fill structures 148, and the second-tier support openings 219 have a 100% areal overlap with the sacrificial support opening fill structures 118. In practice, a finite lithographic overlay error between the pattern of the opening in the second etch mask layer and the first etch mask layer may reduce the percentage of the areal overlap to a range between 50% and 100%. The second etch mask layer can be removed, for example, by ashing after the second anisotropic etch process.

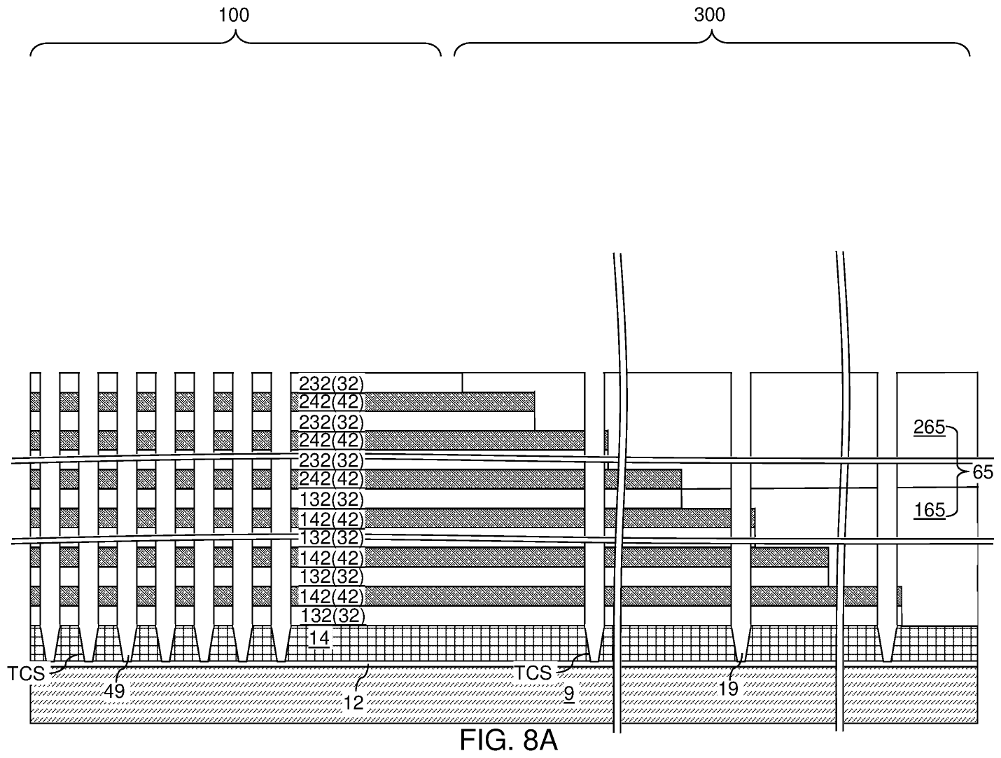

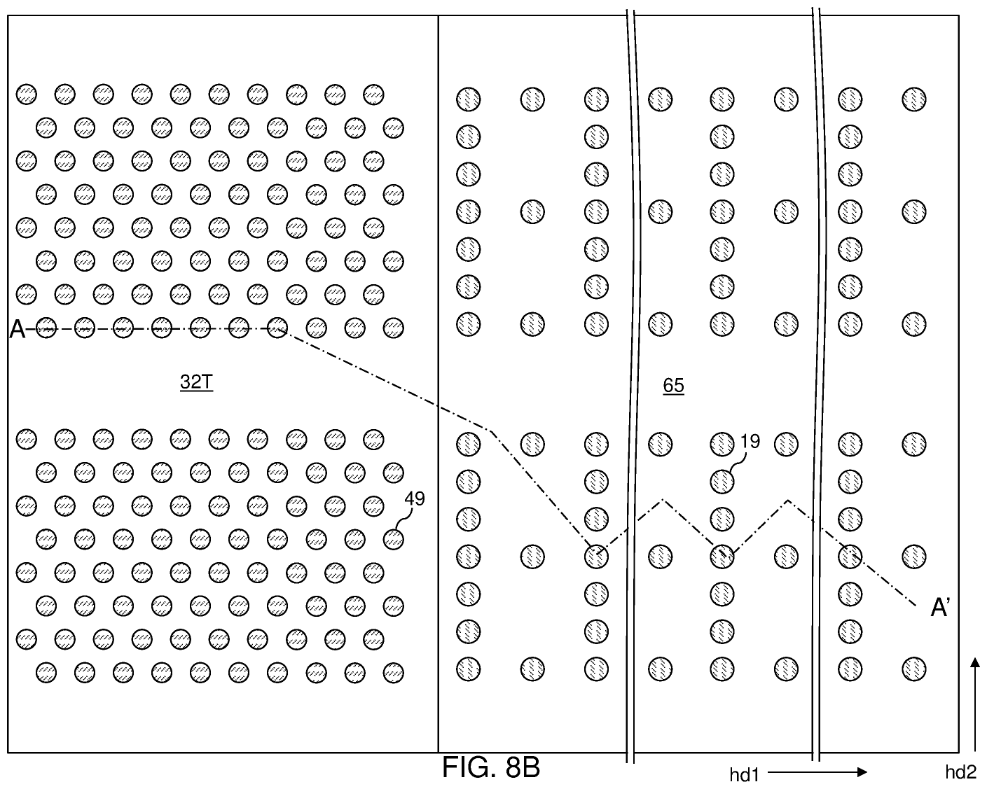

Referring to FIGS. 8A and 8B, the sacrificial memory opening fill structures 148 and the sacrificial support opening fill structures 118 may be removed selective to the materials of the second-tier alternating stack (232, 242), the first-tier alternating stack (132, 142), the stepped dielectric material portion 65, the source-side spacer layer 14, and the backside stopper layer 12. In an illustrative example, if the sacrificial memory opening fill structures 148 and the sacrificial support opening fill structures 118 comprise a carbon-based material, an ashing process may be performed to remove the sacrificial memory opening fill structures 148 and the sacrificial support opening fill structures 118. Inter-tier memory openings 49 (which are also referred to as memory openings 49) can be formed through the second-tier alternating stack (232, 242), the first-tier alternating stack (132, 142), the source-side spacer layer 14, and the backside stopper layer 12, and optionally into an upper portion of the carrier substrate 9. Inter-tier support openings 19 (which are also referred to as support openings 19) can be formed through the stepped dielectric material portion 65, at least through the first-tier alternating stack (132, 142) and optionally through the second-tier alternating stack (232, 242), and through the source-side spacer layer 14 and the backside stopper layer 12, and optionally into an upper portion of the carrier substrate 9.

In summary, a source-side spacer layer 14 can be formed over a carrier substrate 9, and at least one alternating stack of insulating layers 32 and spacer material layers (such as sacrificial material layers 42) may be formed over the source-side spacer layer 14 in the first exemplary structure. The spacer material layers are formed as, or are subsequently replaced with (if formed as sacrificial material layers 42), electrically conductive layers. Memory openings 49 can be formed through the alternating stack (32, 42) in the memory array region 100. The alternating stack (32, 42) may comprise a single-tier structure including a single stepped dielectric material portion, or may comprise a multi-tier structure including a first-tier alternating stack (132, 142) and a first stepped dielectric material portion 165 as a first-tier structure, and a second-tier alternating stack (232, 242) and a second stepped dielectric material portion 265 as a second-tier structure, and optionally including additional tier structures (not shown) that are formed above the second-tier structure.

Each of the memory openings 49 can vertically extend at least to a top surface of the backside stopper layer 12. In one embodiment, bottom surfaces of the memory openings 49 may be formed on a top surface of the backside stopper layer 12. Each cluster of memory openings 49 may comprise a plurality of rows of memory openings 49. Each row of memory openings 49 may comprise a plurality of memory openings 49 that are arranged along the first horizontal direction hd1 with a uniform pitch. The rows of memory openings 49 may be laterally spaced among one another along the second horizontal direction hd2, which may be perpendicular to the first horizontal direction hd2. In one embodiment, each cluster of memory openings 49 may be formed as a two-dimensional periodic array of memory openings 49. The memory openings 49 may have a diameter in a range from 60 nm too 400 nm, such as from 120 nm to 300 nm, although lesser and greater thicknesses may be employed. In the alternative embodiment, the support openings 19 are formed at the same time as the memory openings 49 using the same patterned photoresist layer. In one embodiment, each of the memory openings 49 and support openings 19 may comprise a bottom cavity portion having a shape of an inverted cone or an inverted conical frustum.

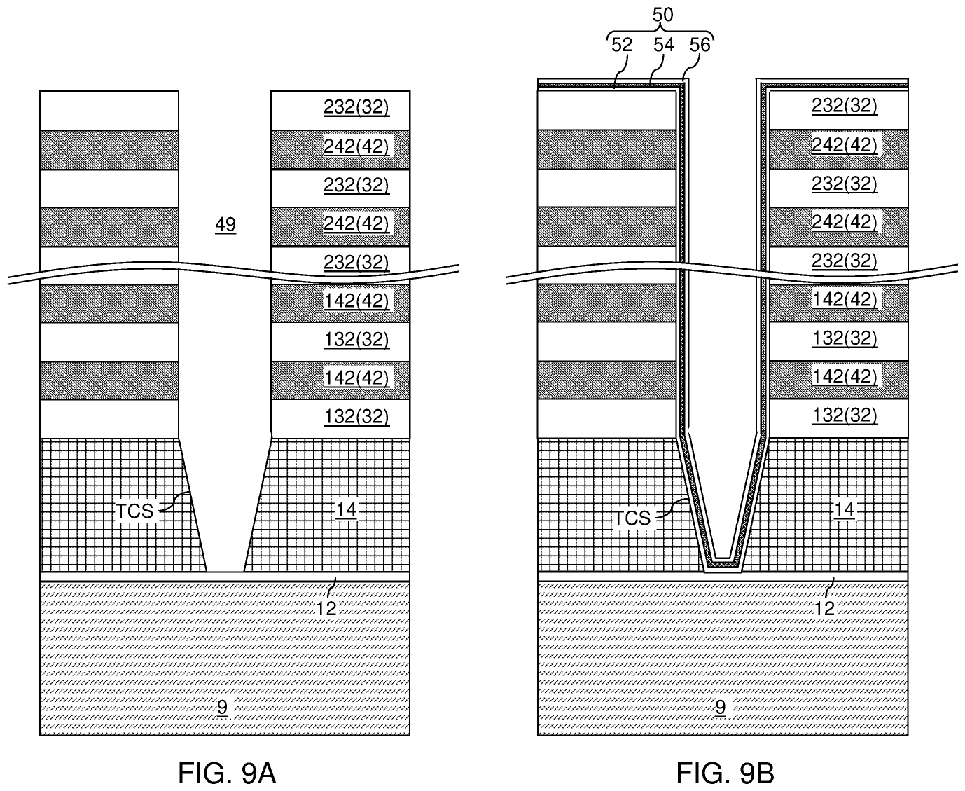

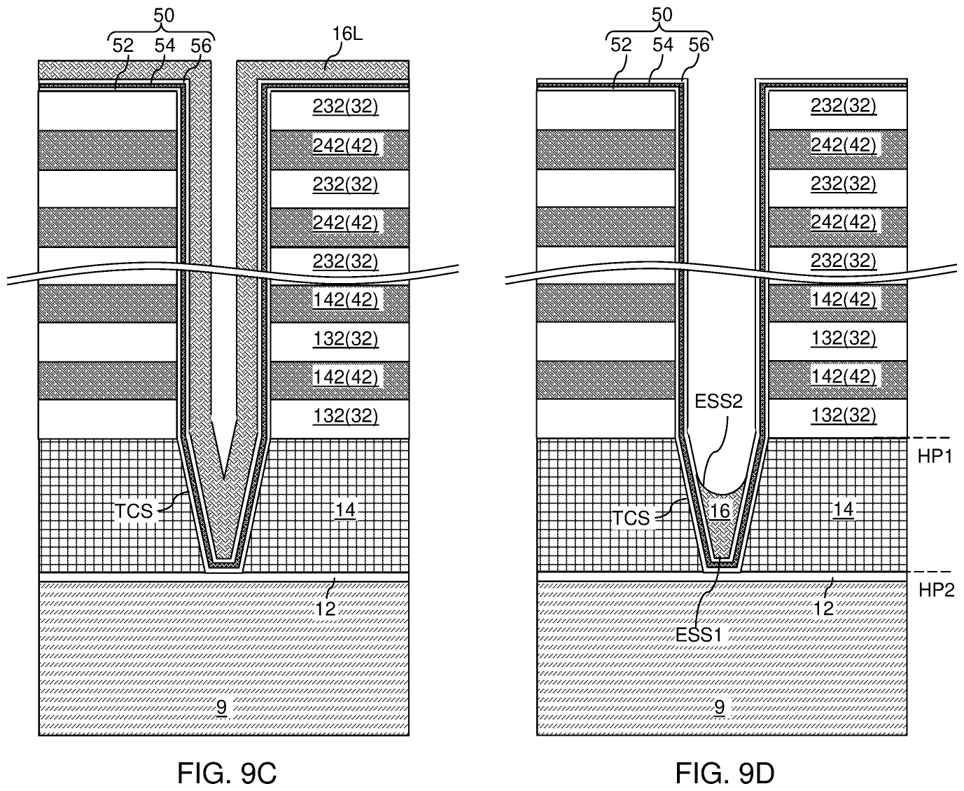

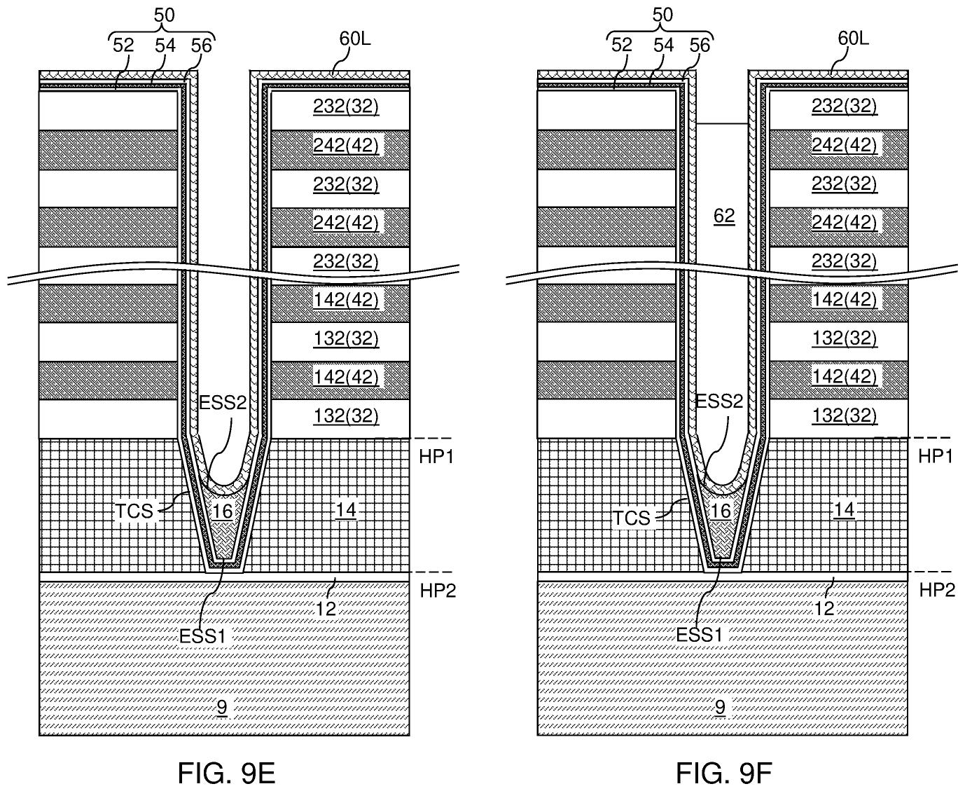

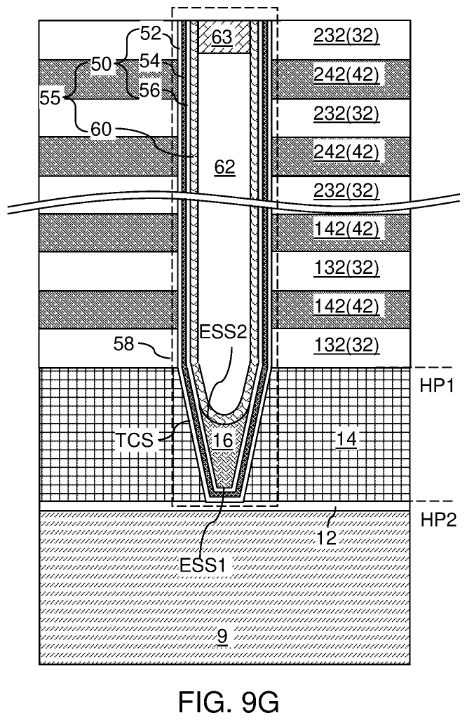

FIGS. 9A-9G are sequential vertical cross-sectional views of a memory opening 49 during formation of a memory opening fill structure 58 in the first exemplary structure according to the first embodiment of the present disclosure. A similar structural change may occur in every other memory opening 49 and in each of the support openings 19 during the processing steps of FIGS. 9A-9G.

Referring to FIG. 9A, a memory opening 49 is illustrated after the processing steps of FIGS. 8A and 8B. The memory opening 49 comprises a cylindrical cavity portion that vertically extends through the at least one alternating stack {(132, 142), (232, 242)}, and a bottom cavity portion having a shape of an inverted cone or an inverted conical frustum and laterally surrounded by a tapered conical sidewall TCS.

Referring to FIG. 9B, a memory film 50 including a memory material layer 54 can be conformally deposited. In an illustrative example, the memory film 50 may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer. The memory film 50 is formed on exposed surfaces of the memory openings 49.

Referring to FIG. 9C, a conformal semiconductor deposition process can be performed to deposit a doped semiconductor fill material in each memory opening 49 and in each support opening 19 to form a conformal doped semiconductor layer 16L. The doped semiconductor fill material has a doping of a second conductivity type, which is the opposite of the first conductivity type of vertical semiconductor channels to be subsequently formed. If the first conductivity type is p-type, the second conductivity type is n-type, and vice versa. For example, the conformal doped semiconductor layer 16L may comprise n-type, phosphorus doped polysilicon or amorphous silicon. The atomic concentration of dopants of the second conductivity type in the doped semiconductor fill material may be in a range form 1.0×10¹⁴/cm³ to 1.0×10²¹/cm³, such as from 1.0×10¹⁶/cm³ to 1.0×10²⁰/cm³, although lesser and greater atomic concentrations may also be employed.

The thickness of the conformal doped semiconductor layer 16L may be greater than one half of the diameter of at least a bottom of the cavity portion having the shape of the inverted cone or an inverted conical frustum, and less than one half of the diameter of each memory opening 49 and may be less than one half of the diameter of each support opening 19 at the levels of the alternating stack (32, 42). In this case, a cavity may be present within each memory opening 49 and within each support opening 19 at the levels of the alternating stack (32, 42), while at least the bottom of the cavity portion having the shape of the inverted cone or an inverted conical frustum is completely filled with the conformal doped semiconductor layer 16L.

Referring to FIG. 9D, an isotropic etch back process may be performed to isotropically recess the conformal doped semiconductor layer 16L. All portions of the conformal doped semiconductor layer 16L can be removed except bottommost portions of the conformal doped semiconductor layer 16L located at bottom portions of conical or frustum-shaped bottom portions of the memory openings 49 and the support openings 19. Removal of the material of the conformal doped semiconductor layer 16L is isotropic during the isotropic etch back process, and thus, remaining portions of the conformal doped semiconductor layer 16L comprise bottommost tip portions of the conformal doped semiconductor layer 16L at a respective bottom portion of the memory openings 49 and the support openings 19. Remaining portions of the conformal doped semiconductor layer 16L in the memory openings 49 after the isotropic etch back process function as topmost capping portions of a source structure, and are hereafter referred to source cap structures 16. The source cap structures 16 is located inside of and is surrounded by the memory film 50.

In summary, the source cap structures 16 may be formed by conformally depositing and isotropically etching a doped semiconductor material, and each remaining portion of the doped semiconductor material comprises a source cap structure 16. Each source cap structure 16 comprises a tapered annular surface that contact a respective memory film 50, and may comprise a first end surface segment ESS1 that contacts an underlying portion of the respective memory film 50. In one embodiment, each source cap structure 16 may comprise a second end surface segment ESS2, which is a concave surface segment that is exposed to an overlying void in a respective memory opening 49 or in a respective support opening 19. In one embodiment, the second end surface segments ESS2 of the source cap structures 16 may be located entirely between a first horizontal plane HP1 including the first horizontal surface (such as a top surface) of the source-side spacer layer 14 and a second horizontal plane HP2 including a second horizontal surface (such as a bottom surface) of the source-side spacer layer 14.

Referring to FIG. 9E, a semiconductor channel material layer 60L can be deposited on the memory film 50 and each of the second end surface segments ESS2 of the source cap structures 16 by performing a conformal deposition process. In one embodiment, the semiconductor channel material layer 60L may be doped with dopants of the first conductivity type, which is the opposite of the second conductivity type. The atomic concentration of dopants of the first conductivity type in the semiconductor channel material layer 60L may be in a range from 1.0×10¹²/cm³ to 3.0×10¹⁷/cm³, such as from 1.0×10¹⁴/cm³ to 3.0×10¹⁶/cm³, although lesser and greater atomic concentrations may also be employed. The thickness of the semiconductor channel material layer 60L may be in a range from 3 nm to 60 nm, such as from 6 nm to 30 nm, although lesser and greater thicknesses may also be employed. In one embodiment, each bottom portion of the semiconductor channel material layer 60L located within a respective memory opening 49 may comprise a convex surface that contacts the concave surface segment ESS2 of a respective source cap structure 16. A p-n junction can be formed at each interface between the semiconductor channel material layer 60L and the source cap structures 16.

Referring to FIG. 9F, a dielectric core layer comprising a dielectric fill material, such as silicon oxide, can be deposited in remaining volumes of the memory openings 49. The dielectric core layer can be vertically recessed such that each remaining portion of the dielectric core layer has a top surface at, or about, the horizontal plane including the bottom surface of a topmost insulating layers 32. Each remaining portion of the dielectric core layer constitutes a dielectric core 62.

Referring to FIG. 9G, a doped semiconductor material having a doping of the second conductivity type can be deposited within each recessed region above the dielectric cores 62. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon. Excess portions of the deposited semiconductor material having a doping of the second conductivity type, a horizontally-extending portion of the semiconductor channel material layer 60L, and a horizontally-extending potion of the memory film 50 can be removed from above the horizontal plane including the top surface of the topmost layer of the alternating stack (32, 42), for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60. Each drain region 63 has a doping of the second conductivity type, and is located at a top end of the vertical semiconductor channel 60 that is located at an opposite side of a bottom end that contacts the source cap structure 16.

Each contiguous combination of a memory film 50 and a vertical semiconductor channel 60 constitutes a memory stack structure 55. The set of all material portions that fills a memory opening 49 constitutes a memory opening fill structure 58. The set of all material portions that fills a support opening 19 constitutes a support pillar structure. Each memory opening fill structure 58 can be located in a memory opening 49, and can comprise a memory film 50, a vertical semiconductor channel 60, a source cap structure 16, a dielectric core 62, and a drain region 63.

In summary, a memory opening 49 vertically extends through the alternating stack (32, 42) and through the source-side spacer layer 14. Within each memory opening 49, a memory film 50 is formed at a peripheral portion of the memory opening 49, a source cap structure 16 is formed at a bottom portion of the inner sidewall of the memory film 50, and a vertical semiconductor channel 60 is formed on a top surface of the source cap structure 16 and on an inner sidewall of the memory film 50. In each memory opening fill structure 58, the vertical semiconductor channel 60 comprises dopants of a first conductivity type at a first atomic concentration, and the source cap structure 16 comprises dopants of a second conductivity type that is an opposite of the first conductivity type at a second atomic concentration that is higher than the first atomic concentration.

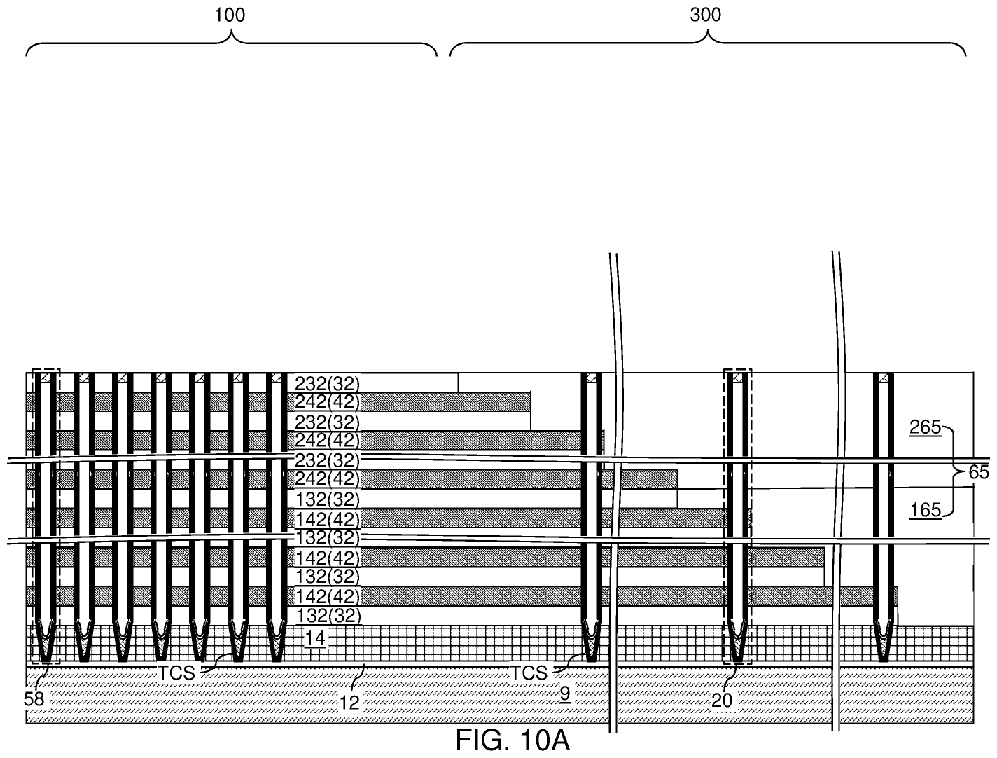

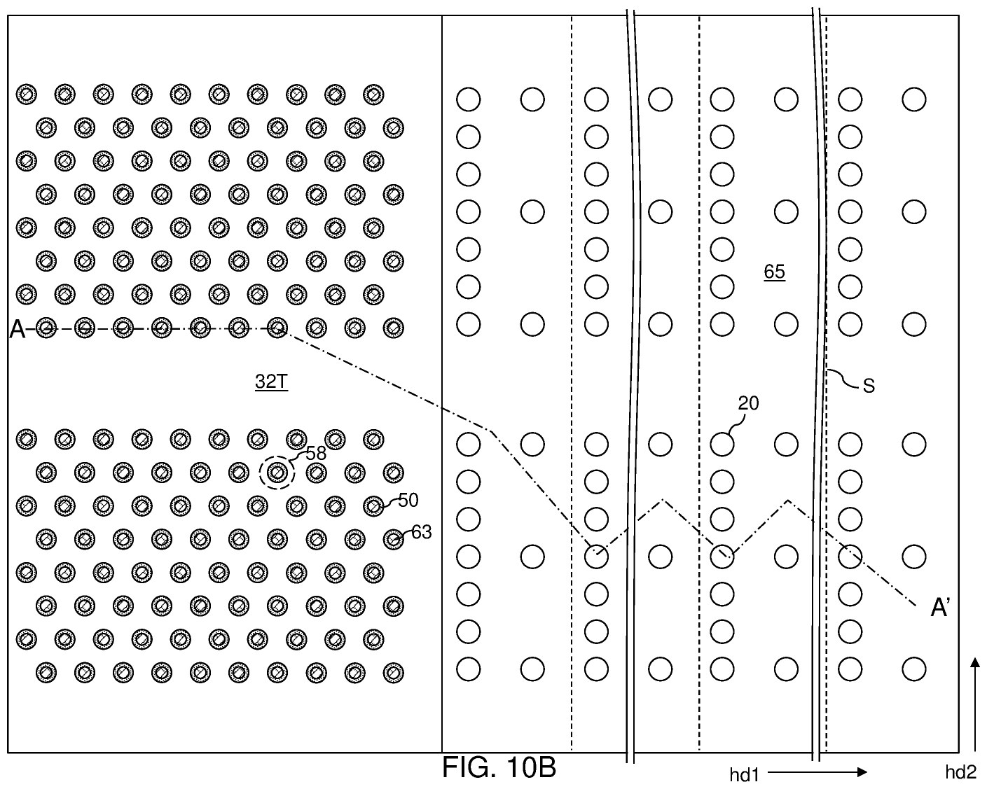

Referring to FIGS. 10A and 10B, the first exemplary structure is illustrated after formation of memory opening fill structures 58 within the memory openings 49 and formation of the support pillar structures 20 in the support openings 19. Each of the support pillar structures 20 may have a same set of materials as a memory opening fill structure 58. Alternatively, the support pillar structures 20 may include only an insulating material, such as silicon oxide. In this alternative embodiment, the support openings 19 are filled with silicon oxide before or after forming the memory opening fill structures 58.

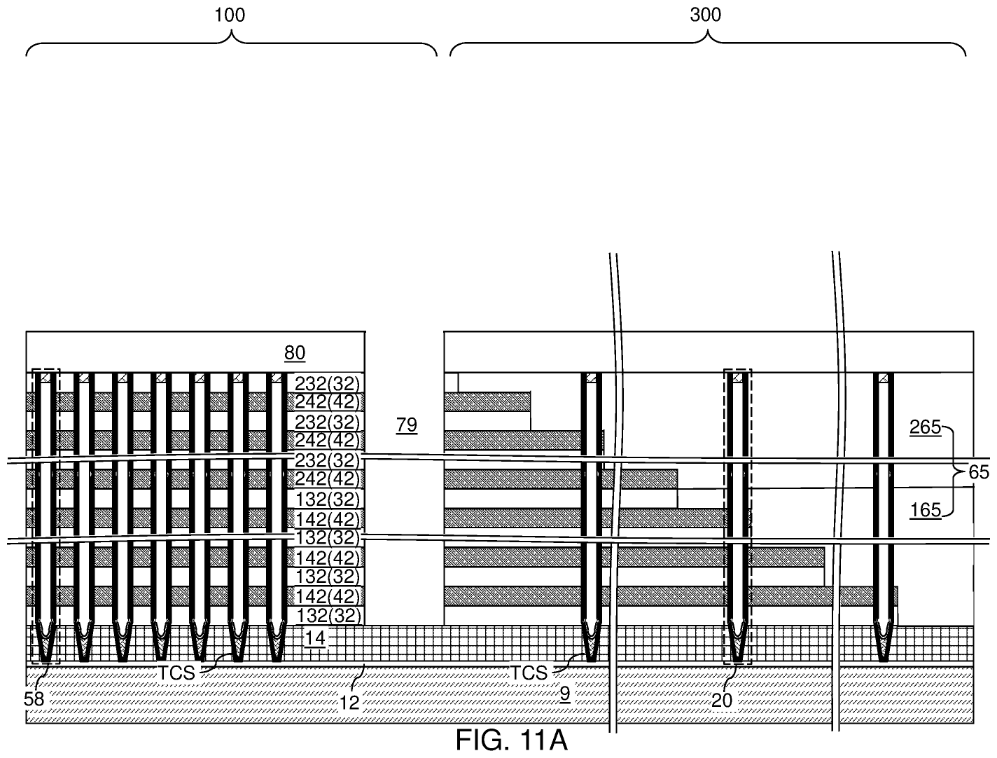

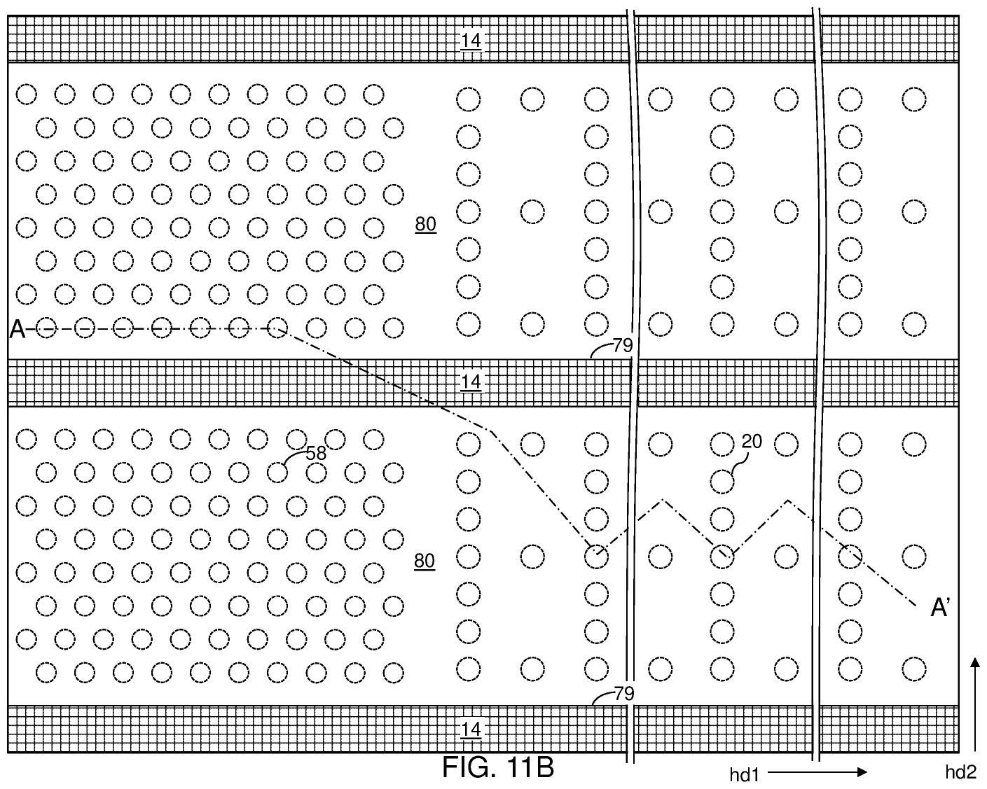

Referring to FIGS. 11A and 11B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and at least to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the carrier substrate 9 to the top surface of the contact-level dielectric layer 80. A surface of the carrier substrate 9 can be physically exposed underneath each lateral isolation trench 79. The photoresist layer can be subsequently removed, for example, by ashing.

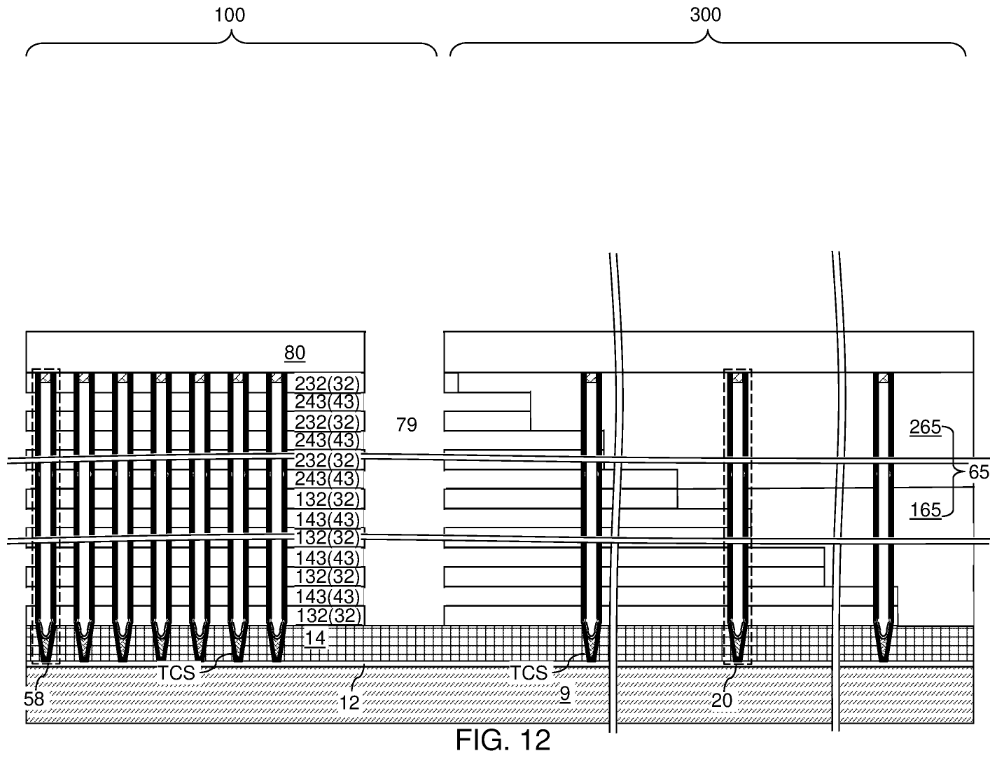

Referring to FIG. 12, an etchant that selectively etches the material of the sacrificial material layers 42 with respect to the material of the insulating layers 32, the source-side spacer layer 14, and the carrier substrate 9 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43. The lateral recesses 43 comprise first lateral recesses 143 that are formed in volumes from which the first sacrificial material layers 142 are removed, and further comprise second lateral recesses 243 that are formed in volumes from which the second sacrificial material layers 242 are removed.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

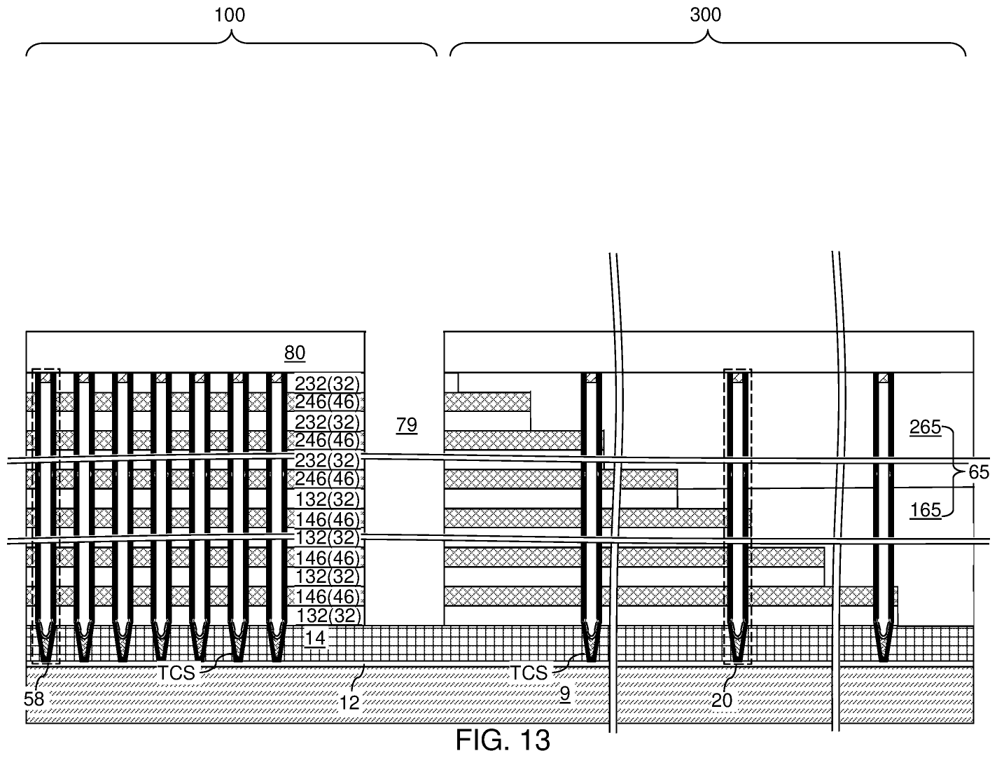

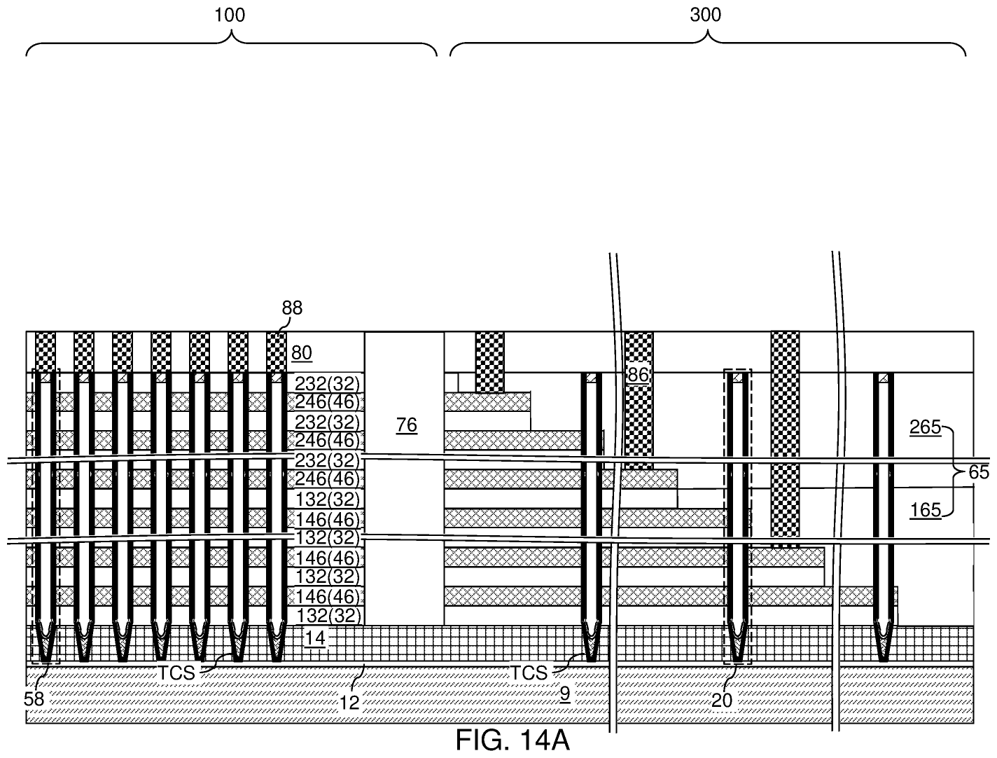

Referring to FIG. 13, an outer blocking dielectric layer (not expressly illustrated in FIG. 13) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, MoN or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. The electrically conductive layers 46 comprise first electrically conducive layers 146 that are formed in the volumes of the first lateral recesses 143 and replace the first sacrificial material layers 142, and further comprise second electrically conductive layers 246 that are formed in the volumes of the second lateral recesses 243 and replace the second sacrificial material layers 242. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a respective drain-side select gate electrode. At least one bottommost electrically conductive layer 46 may comprise a respective source-side select gate electrode. The remaining electrically conductive layers 46 may comprise word lines. Each word line functions as a common control gate electrode for the plurality of vertical NAND strings (e.g., memory opening fill structures 58).

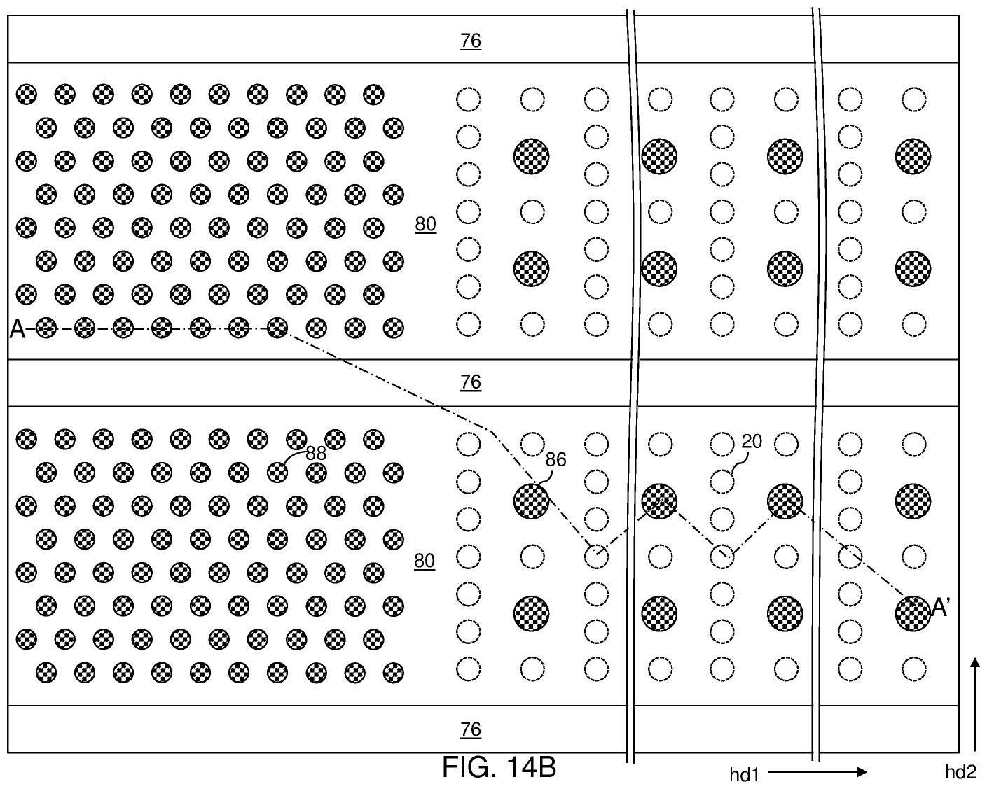

Referring to FIGS. 14A and 14B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

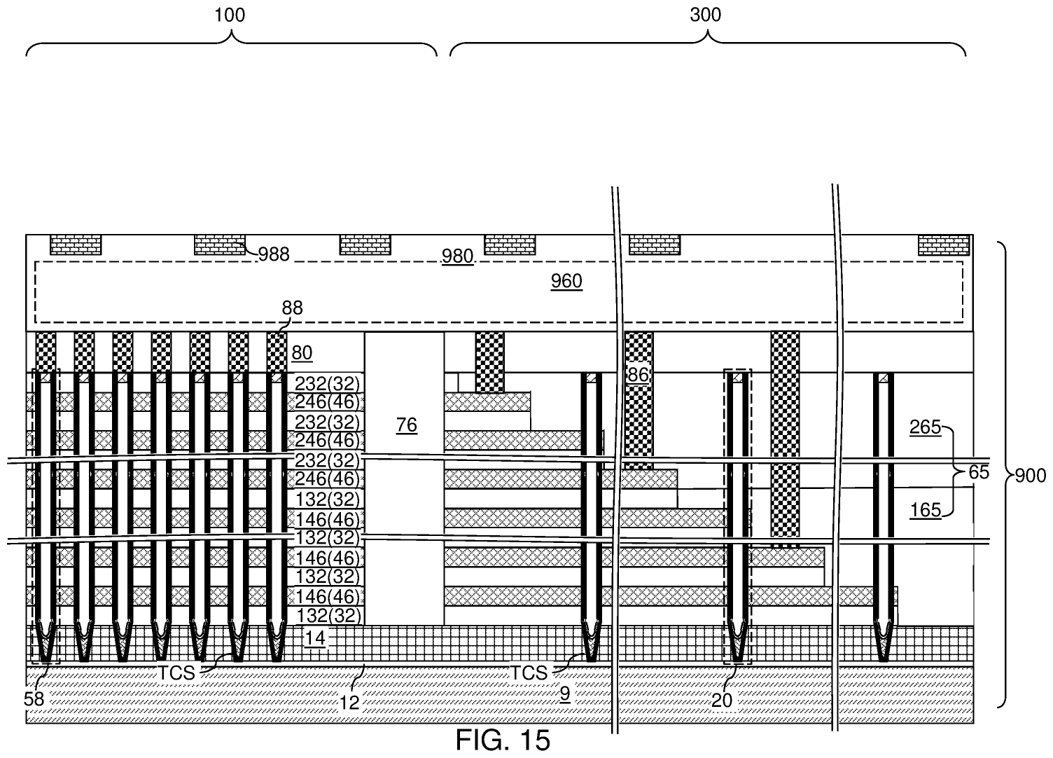

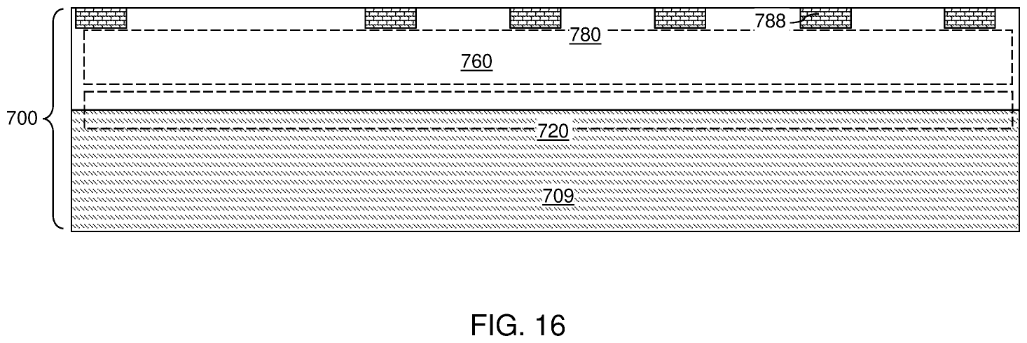

Referring to FIG. 15, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

Referring to FIG. 16, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

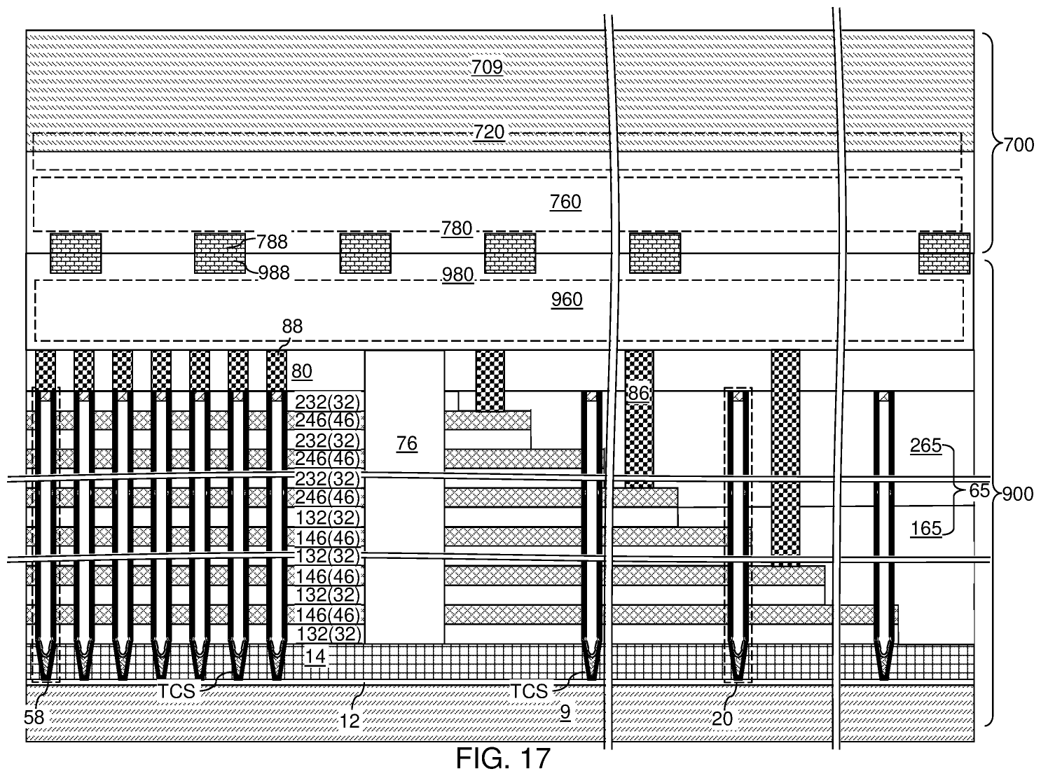

Referring to FIG. 17, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

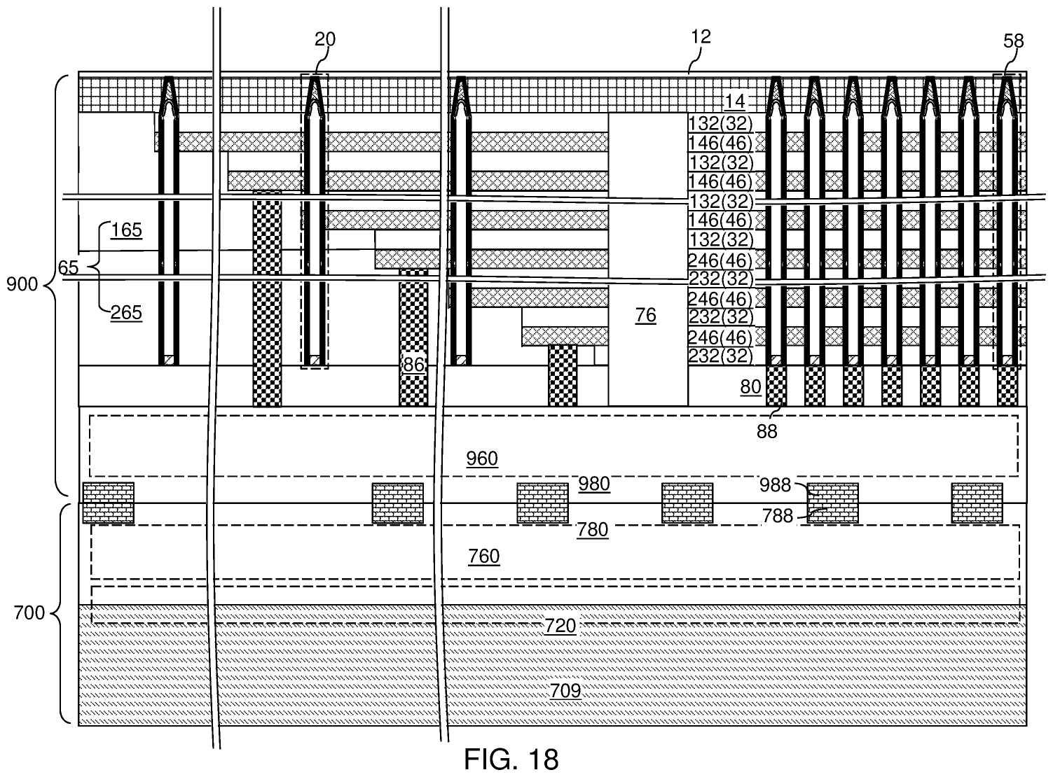

Referring to FIG. 18, the carrier substrate 9 can be removed, for example, by grinding, polishing, cleaving, an isotropic etch process, and/or an anisotropic etch process. The backside stopper layer 12 may be employed as a stopping structure during a terminal processing step that is employed to remove the carrier substrate 9. For example, if the carrier substrate 9 comprises silicon, the backside of the carrier substrate 9 can be thinned by performing at least one process step that removes a predominant portion of the carrier substrate 9 from the backside, and a terminal processing step that may include a wet etch process employing KOH, which can etch the silicon of a remaining portion of the carrier substrate 9 selective to the material of the backside stopper layer 12 (which may include a dielectric material, such as silicon oxide).

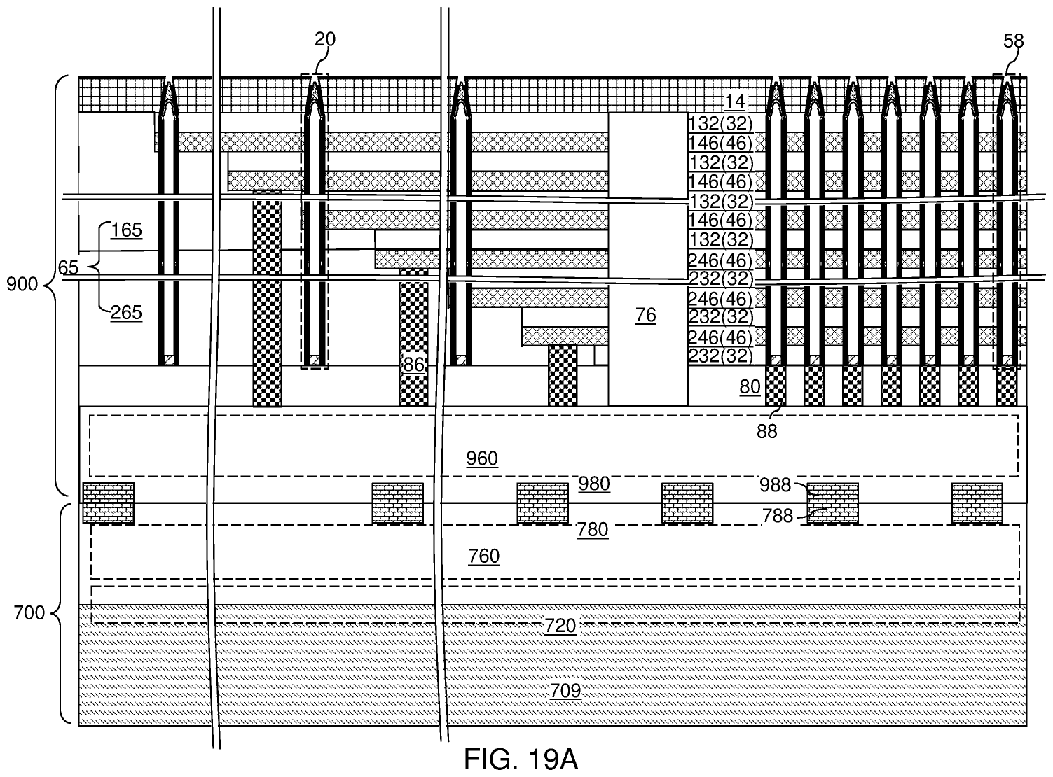

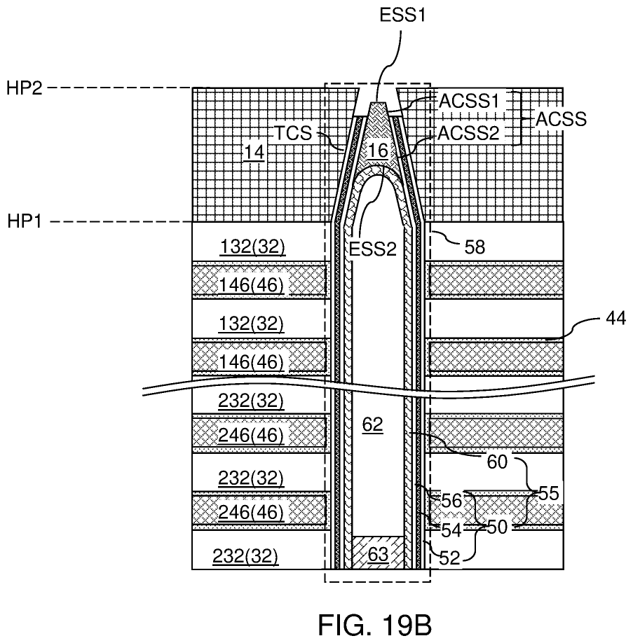

Referring to FIGS. 19A and 19B, the backside stopper layer 12 and end portions of the memory films 50 can be removed by performing a sequence of etch processes. The optional outer blocking dielectric layers 44 are expressly shown in FIG. 19B.

In an illustrative example, a first etch process that etches the material of the backside stopper layer 12 can be performed. If the backside stopper layer 12 comprises silicon oxide, a wet etch process employing dilute hydrofluoric acid can be employed as the first etch process to remove the backside stopper layer 12 selective to the material of the source-side spacer layer 14 (which may comprise a semiconductor material, such as polysilicon). If the blocking dielectric layers 52 comprise silicon oxide, end portions of the blocking dielectric layers 52 that are proximal to the backside stopper layer 12 may be collaterally removed during the first etch process.

Subsequently, a second etch process can be performed to remove end portions of the memory material layers 54 selective to the material of the dielectric liner 56 and the source-side spacer layer 14. If the memory material layers 54 comprise silicon nitride, a wet etch process employing hot phosphoric acid or a mixture of dilute hydrofluoric acid and ethylene glycol can be employed as the second etch process to remove end portions of the memory material layers 54 that are exposed to voids in the openings in the source-side spacer layer 14.

Further, a third etch process can be performed to remove end portions of the dielectric liners 56 selective to the material of source cap structures 16 and the source-side spacer layer 14. If the dielectric liners 56 comprise silicon oxide and/or silicon oxynitride, a wet etch process employing dilute hydrofluoric acid or another suitable etchant solution can be employed as the third etch process to remove end portions of the dielectric liners 56 that are exposed to voids in the openings in the source-side spacer layer 14.

A first end surface segment ESS1 of each source cap structure 16 can be physically exposed after the sequence of etch processes. Each source cap structure 16 may comprise a second end surface segment ESS2 that contacts a convex end surface of a vertical semiconductor channel 60. Each source cap structure 16 may comprise an annular conical surface segment ACSS which comprises a first tapered annular area ACSS1 that is physically exposed to a void in a respective opening in the source-side spacer layer 14, and a second tapered annular area ACSS2 in contact with a memory film 50.

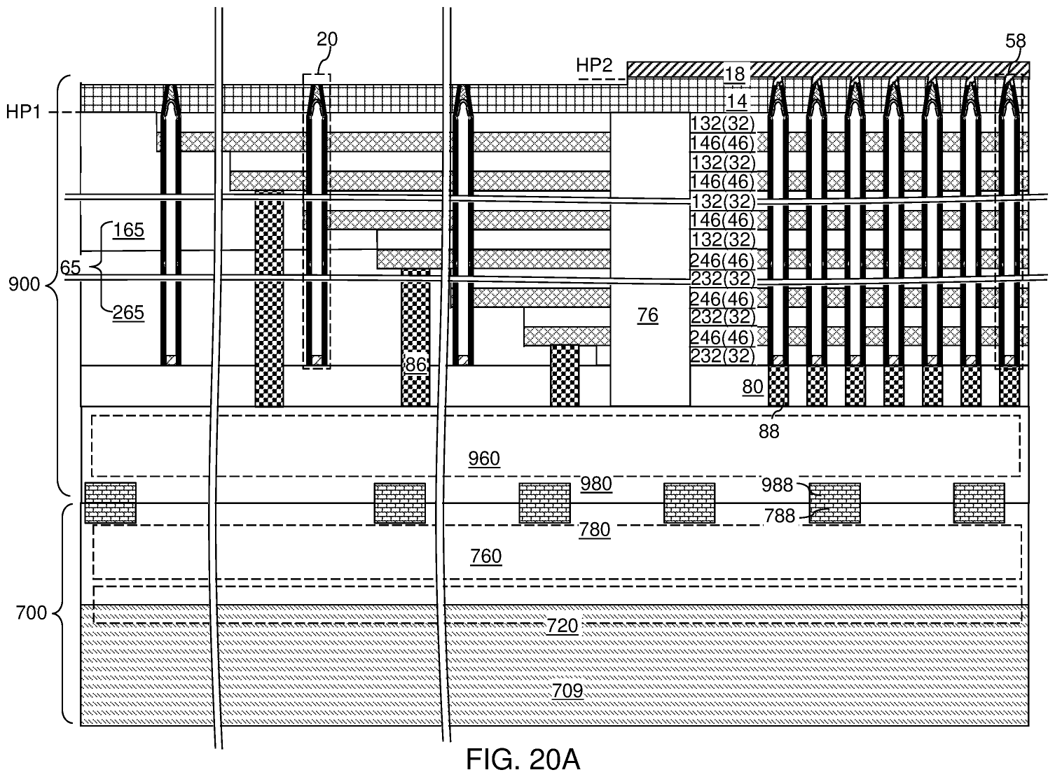

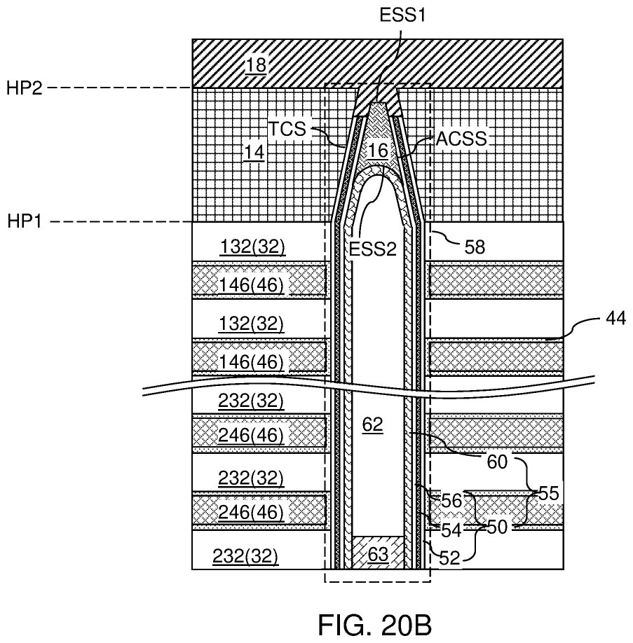

Referring to FIGS. 20A and 20B, a source layer 18 can be formed by depositing at least one electrically conductive material within the voids of the openings in the source-side spacer layer 14 and on the physically exposed planar backside surface of the source-side spacer layer 14. The source layer 18 may comprise a stack of an optional metallic barrier material (such as TiN, TaN, WN, MoN, TiC, TaC, WC, etc.) and a high-electrical-conductivity metal material (such as Cu, Mo, W, Ti, Ta, Co, Ru, etc.).

If the support pillar structures comprise a semiconductor material, then a photoresist layer (not shown) can be applied over the source layer 18 and can be lithographically patterned to cover the areas of the memory opening fill structures 58 in the memory array region 100 without covering the areas of the support pillar structures 20 in the contact region 300. Unmasked portions of the material of the source layer 18 can be removed by performing an etch process. The semiconductor material in the support pillar structures 20 can be electrically isolated from the source layer 18. Alternatively, if the support pillar structures 20 only include an insulating material, then source layer 18 patterning step may be omitted or modified.

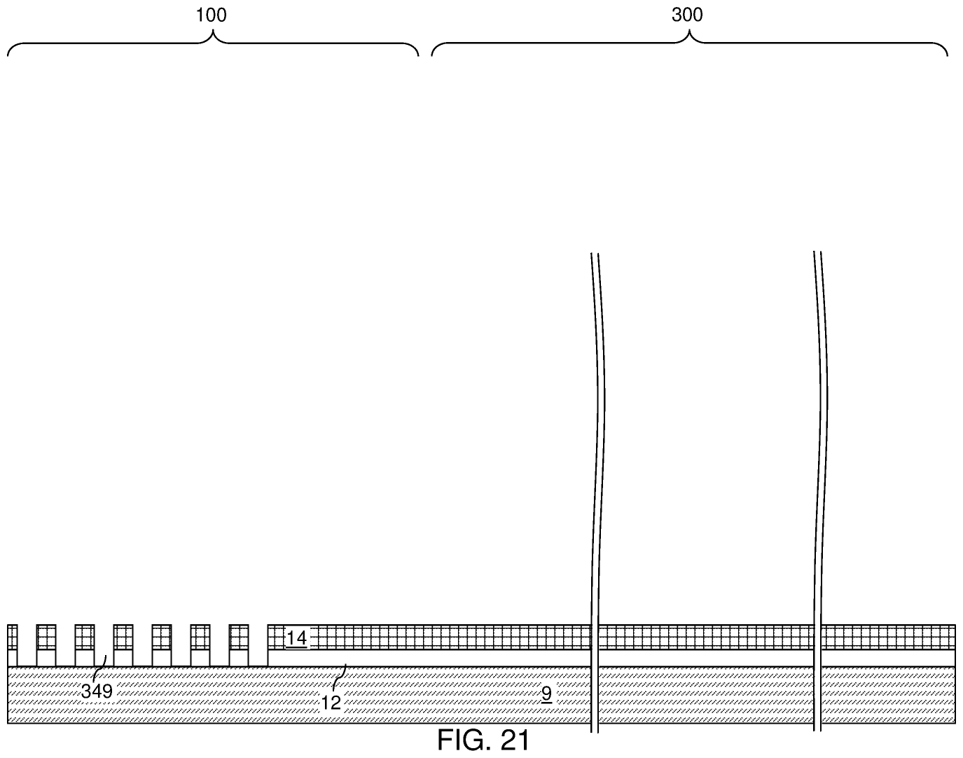

Referring to FIG. 21, a second exemplary structure according to a second embodiment of the present disclosure can be derived from the first exemplary structure illustrated in FIG. 1 by increasing the thickness of the backside stopper layer 12. Specifically, the thickness of the backside stopper layer 12 can be selected to be greater than twice the thickness of a memory film 50 to be subsequently formed. For example, the thickness of the backside stopper layer 12 may be in a range from 30 nm to 300 nm, such as from 60 nm to 150 nm, although lesser and greater thicknesses may also be employed. The source-side spacer layer 14 can be formed on the top surface of the backside stopper layer 12.

A photoresist layer (not shown) can be applied over the top surface of the source-side spacer layer 14, and can be lithographically patterned to form an array of openings having a same pattern as the array of first-tier memory openings 149 illustrated in FIG. 4. An anisotropic etch process can be performed to transfer the pattern of the openings in the photoresist layer through the source-side spacer layer 14 and the backside stopper layer 12. The carrier substrate 9 may be employed as a stopper structure for the anisotropic etch process. An array of discrete source-level openings 349 can be formed through the source-side spacer layer 14 and the backside stopper layer 12. The discrete source-level openings 349 may have cylindrical sidewalls that vertically extend through the source-side spacer layer 14 and the backside stopper layer 12.

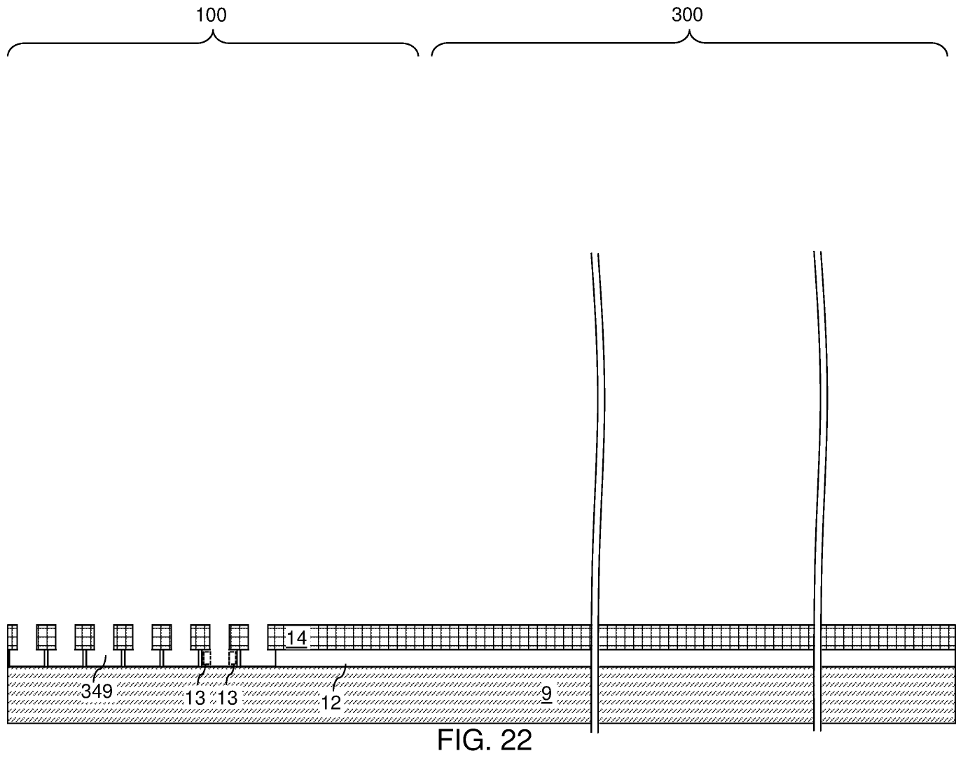

Referring to FIG. 22, an isotropic etch process, such as a wet etch process, may be performed, which etches the material of the backside stopper layer 12 selective to the materials of the source-side spacer layer 14 and the carrier substrate 9. For example, if the source-side spacer layer 14 and the carrier substrate 9 comprise semiconductor materials, such as silicon, and if the backside stopper layer 12 comprises silicon oxide, a wet etch process employing dilute hydrofluoric acid can be performed to laterally recess the backside stopper layer 12 selective to the source-side spacer layer 14 and the backside stopper layer 12.

The lateral etch distance of the isotropic etch process is less than one half of a nearest neighbor spacing among the discrete source-level openings 349 to prevent merging of the discrete source-level openings 349. Further, the lateral etch distance of the isotropic etch process may be greater than the thickness of memory films 50 to be subsequently formed. In one embodiment, the lateral etch distance of the isotropic etch process may be in a range from 15 nm to 100 nm, such as from 30 nm to 60 nm, although lesser and greater thicknesses may also be employed. Each volume of a void formed by lateral recessing of the backside stopper layer 12 constitutes an annular recess cavity 13. Generally, an annular recess cavity 13 can be formed around each discrete source-level opening 349 at the level of the backside stopper layer 12.

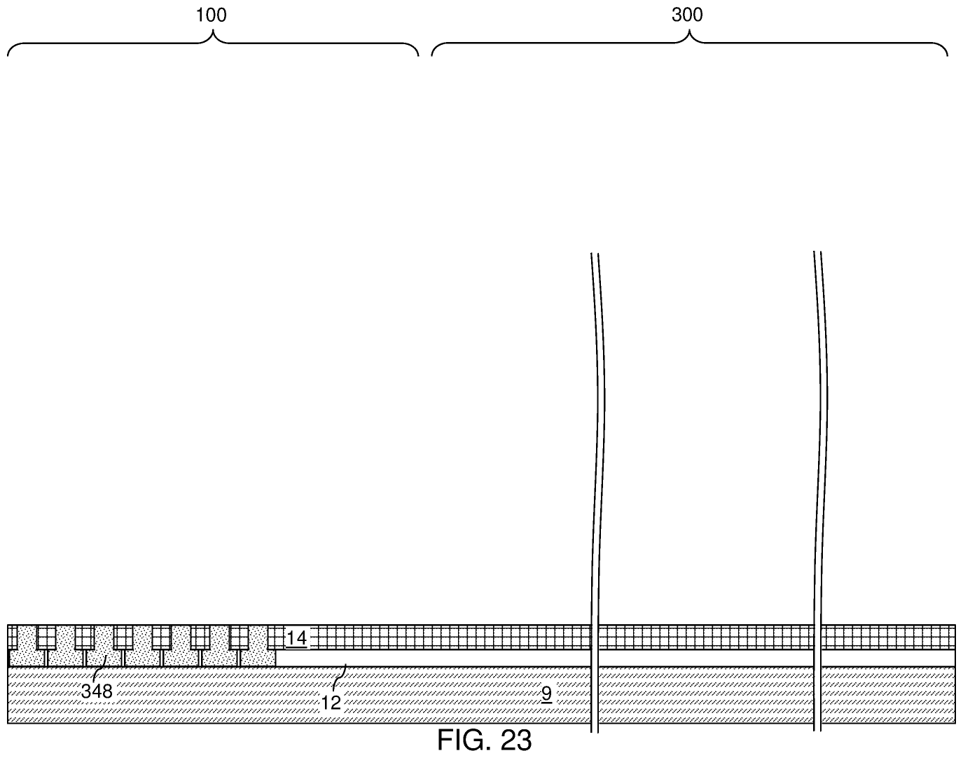

Referring to FIG. 23, a sacrificial fill material can be deposited in the discrete source-level openings 349. The sacrificial fill material may comprise a carbon-based material (e.g., amorphous carbon, diamond-like carbon, or a doped carbon material), a high etch-rate dielectric material (e.g., borosilicate glass or organosilicate glass), or a polymer material. Excess portions of the sacrificial fill material can be removed from above a horizontal plane including the top surface of the source-side spacer layer 14, for example, by a recess etch process. Each remaining portion of the sacrificial fill material filling a respective discrete source-level opening 349 constitutes a sacrificial pedestal structure 348. Each sacrificial pedestal structure 348 may comprise an upper cylindrical portion located at the level of the source-side spacer layer 14 and a lower cylindrical portion located at the level of the backside stopper layer 12. A two-dimensional array of sacrificial pedestal structures 348 can be formed.

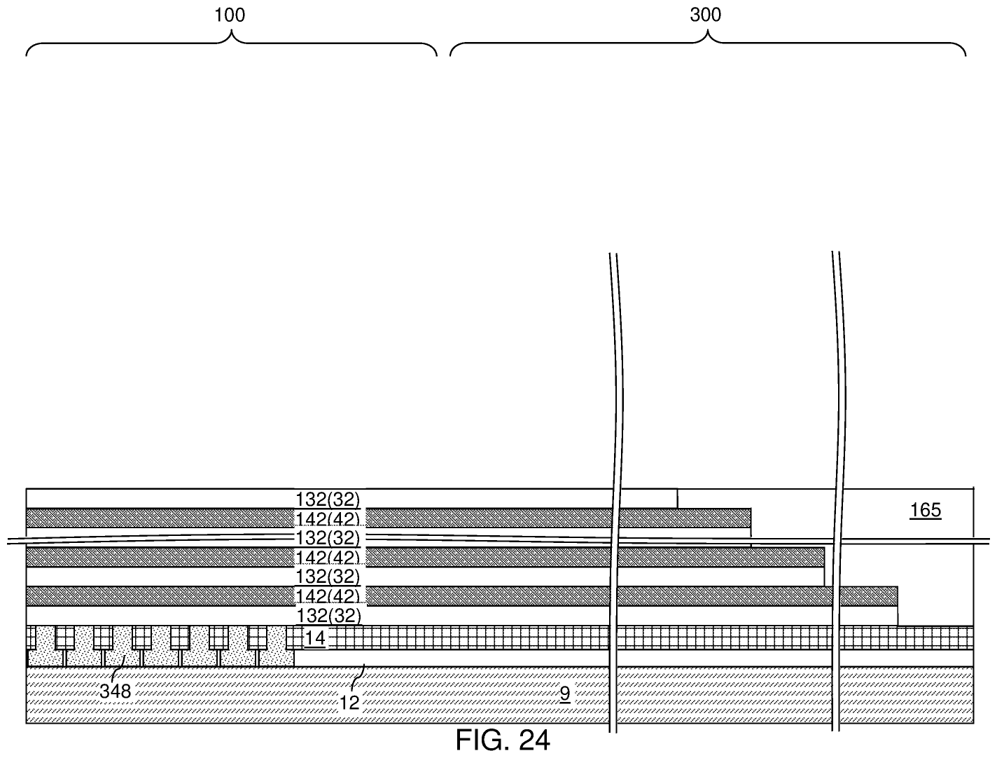

Referring to FIG. 24, the processing steps described with reference to FIGS. 2 and 3 can be performed to form a first-tier alternating stack (132, 142) of first insulating layers 132 and first sacrificial material layers 142, first stepped surfaces, and a first stepped dielectric material portion 165.

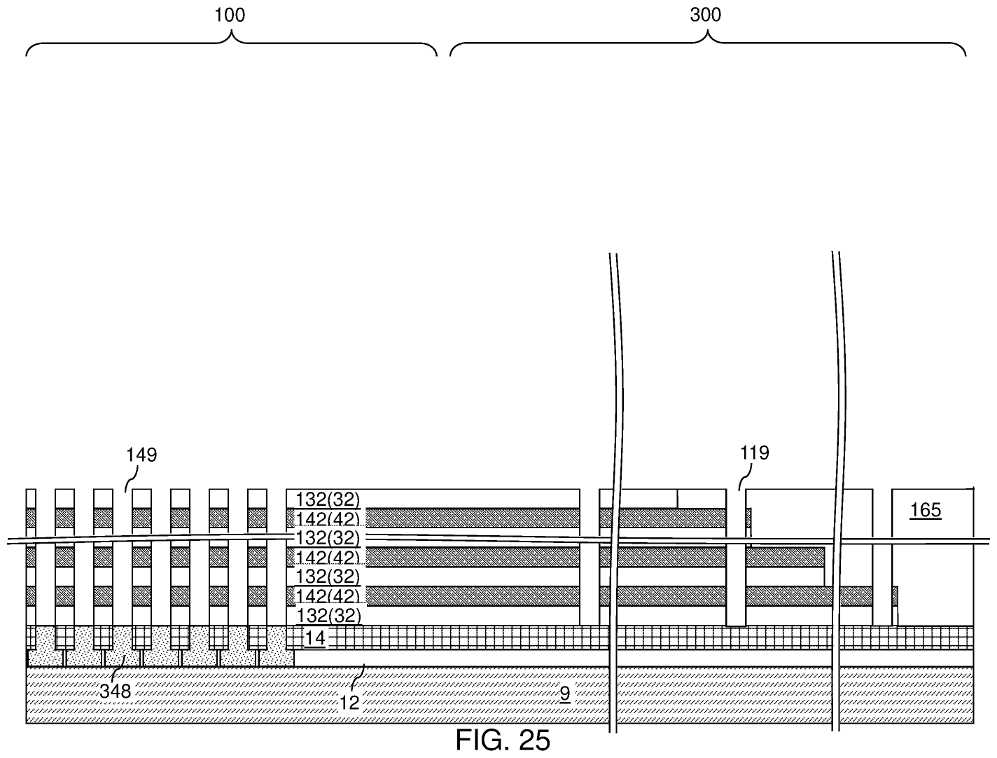

Referring to FIG. 25, the processing steps described with reference to FIG. 4 can be performed with a modification in the anisotropic etch process to form first-tier memory openings 149 and first-tier support openings 119. Specifically, the anisotropic etch process can be modified to etch through unmasked portions of the first-tier alternating stack (132, 142) without etching the materials of the source-side spacer layer 14 or the sacrificial pedestal structures 348.

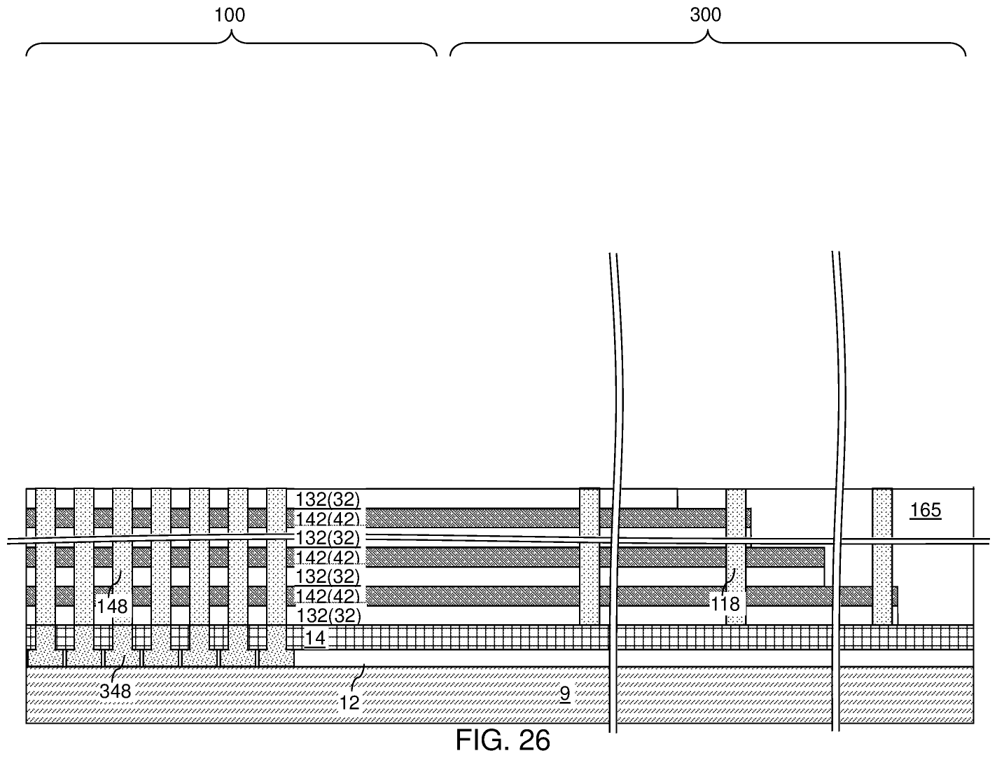

Referring to FIG. 26, the processing steps described with reference to FIG. 5 can be performed to form sacrificial memory opening fill structures 148 in the first-tier memory openings 149 and to form sacrificial support opening fill structures 118 in the first-tier support openings 119.

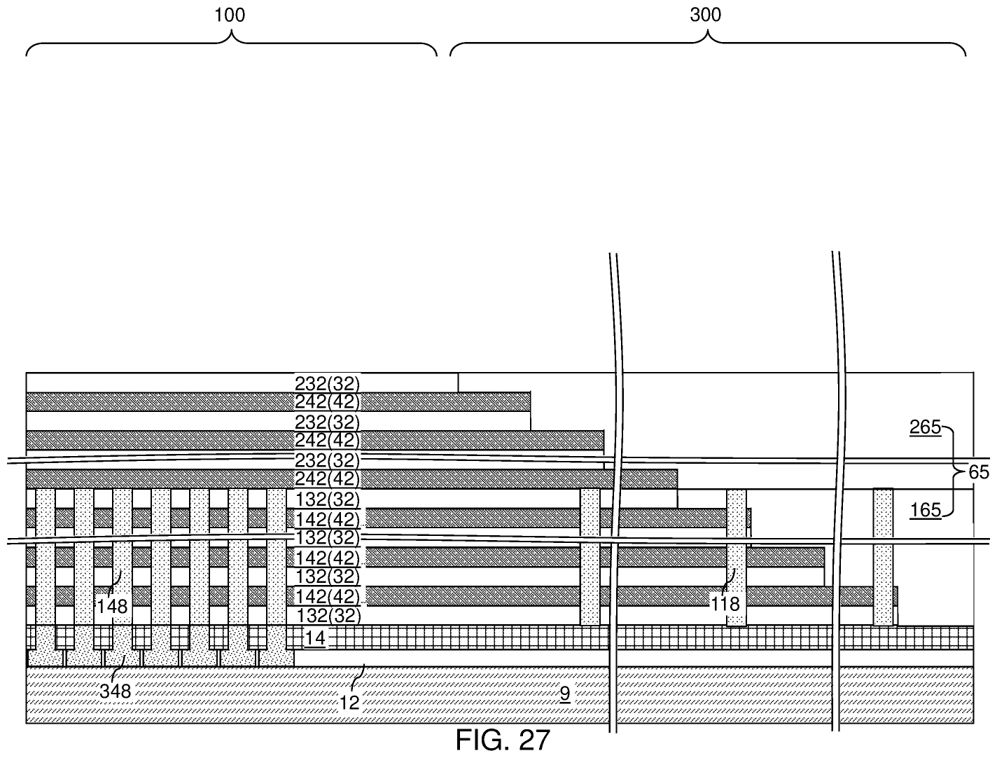

Referring to FIG. 27, the processing steps described with reference to FIG. 6 can be performed to form a second-tier alternating stack (232, 242) of second insulating layers 232 and second spacer material layers (such as second sacrificial material layers 242), second stepped surfaces, and a second stepped dielectric material portion 265.

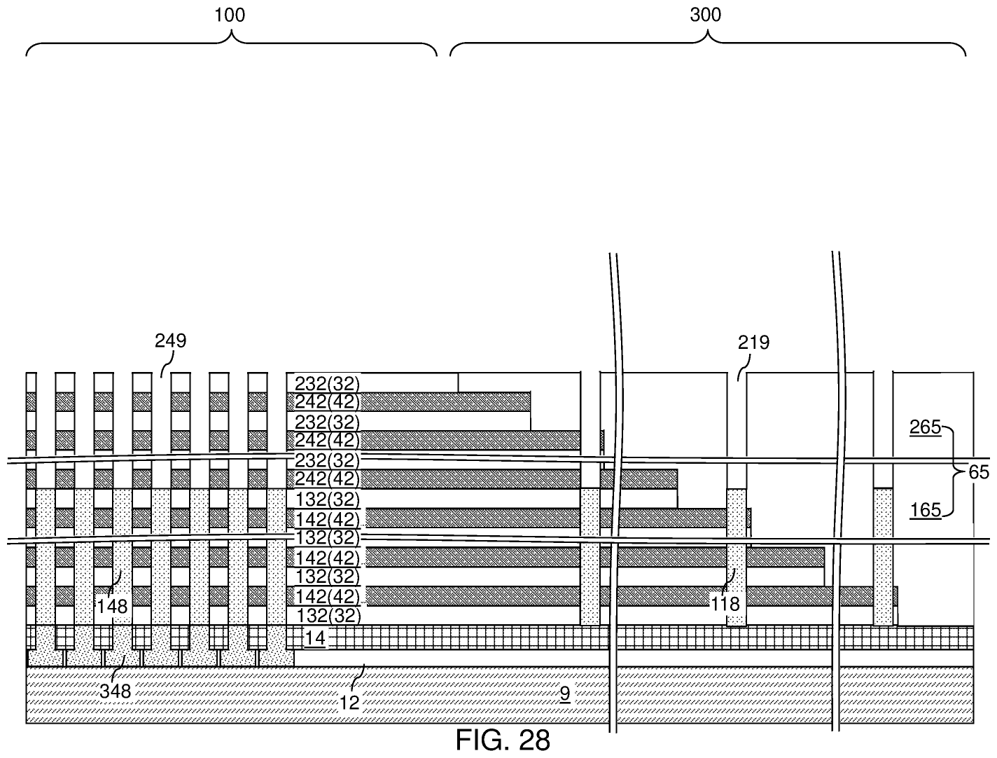

Referring to FIG. 28, the processing steps described with reference to FIG. 7 can be performed to form second-tier memory openings 249 through the second-tier alternating stack (232, 242) directly on a top surface of a respective sacrificial memory opening fill structure 148, and to form second-tier support openings 219 through the second stepped dielectric material portion 165 and the second-tier alternating stack (232, 242) directly on a top surface of a respective sacrificial support opening fill structure 118.

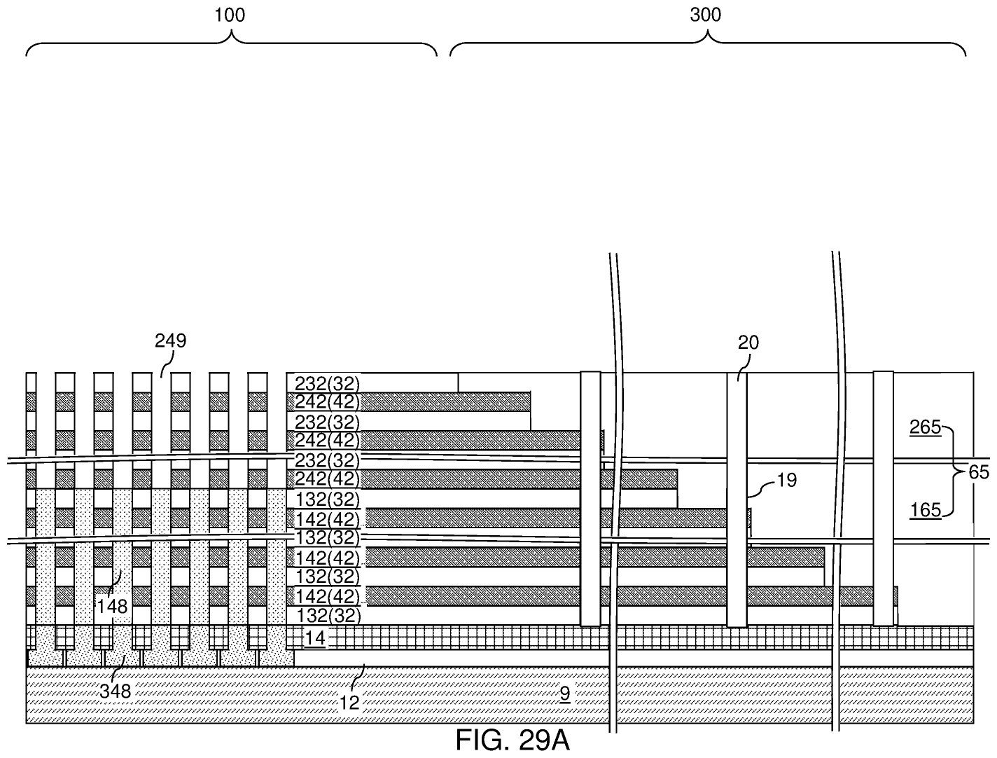

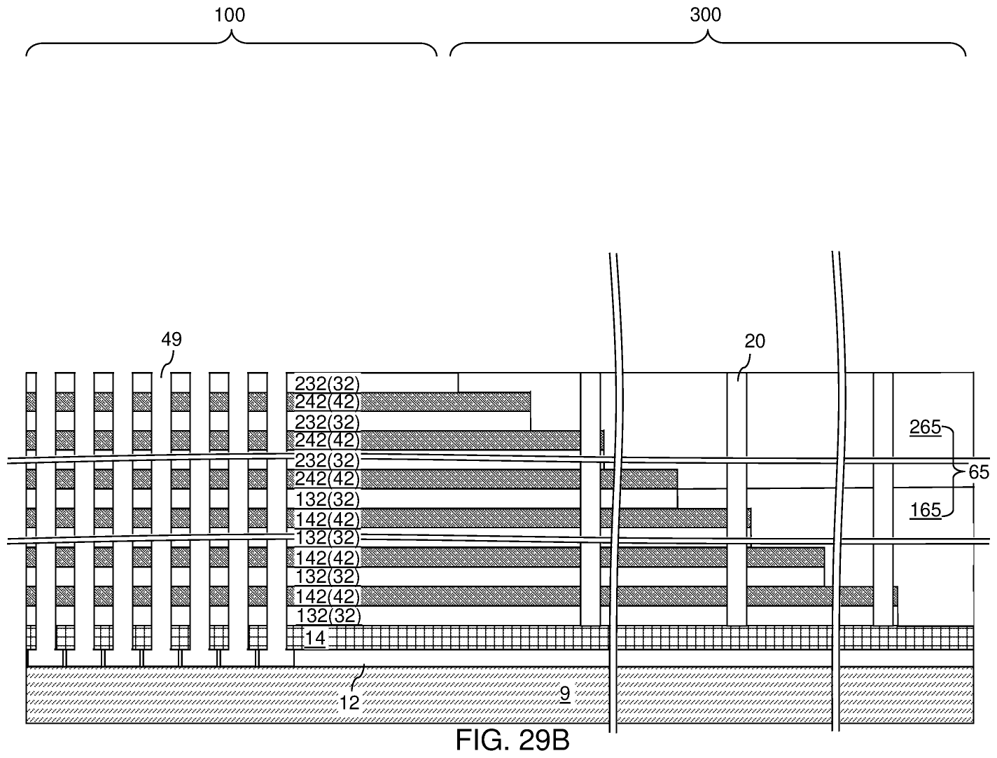

Referring to FIG. 29A, a masking layer (not shown) may be formed over the second-tier memory openings 249. The sacrificial support opening fill structures 118, may be removed selective to the materials of the second-tier alternating stack (232, 242), the first-tier alternating stack (132, 142), the stepped dielectric material portion 65, the source-side spacer layer 14, the backside stopper layer 12, and the carrier substrate 9. In an illustrative example, if the sacrificial support opening fill structures 118, comprise a carbon-based material, an ashing process may be performed to remove the sacrificial support opening fill structures 118. Inter-tier support openings 19 (which are also referred to as support openings 19) can be formed through the stepped dielectric material portion 65, at least through the first-tier alternating stack (132, 142), and optionally through the second-tier alternating stack (232, 242).

The support openings 19 are then filled with an insulating material, such as silicon oxide. The insulating material is then planarized to leave dielectric support pillar structures 20 filling the support openings. The dielectric support structures 20 consist of an insulating material, such as silicon oxide. The masking layer is then removed by selective etching.

Referring to FIG. 29B, the sacrificial memory opening fill structures 148 and the sacrificial pedestal structures 348 may be removed selective to the materials of the support pillar structures 20, the second-tier alternating stack (232, 242), the first-tier alternating stack (132, 142), the stepped dielectric material portion 65, the source-side spacer layer 14, the backside stopper layer 12, and the carrier substrate 9. In an illustrative example, if the sacrificial memory opening fill structures 148 and the sacrificial pedestal structures 348 comprise a carbon-based material, an ashing process may be performed to remove the sacrificial memory opening fill structures 148 and the sacrificial pedestal structures 348. Inter-tier memory openings 49 (which are also referred to as memory openings 49) can be formed through the second-tier alternating stack (232, 242), the first-tier alternating stack (132, 142), the source-side spacer layer 14, and the backside stopper layer 12.

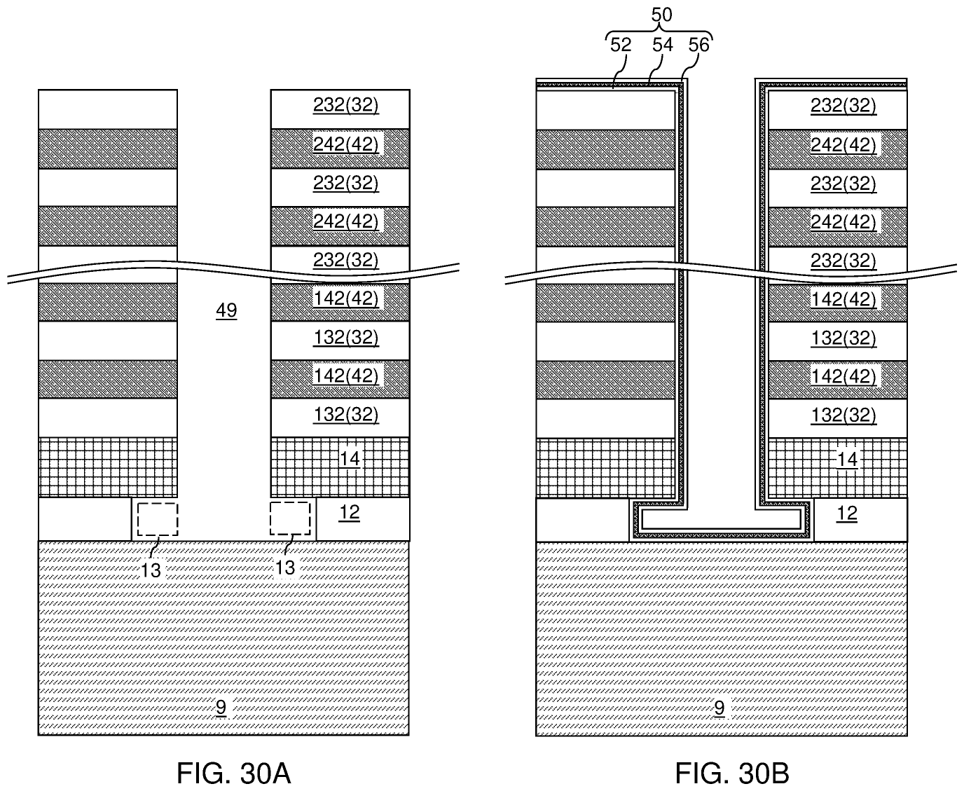

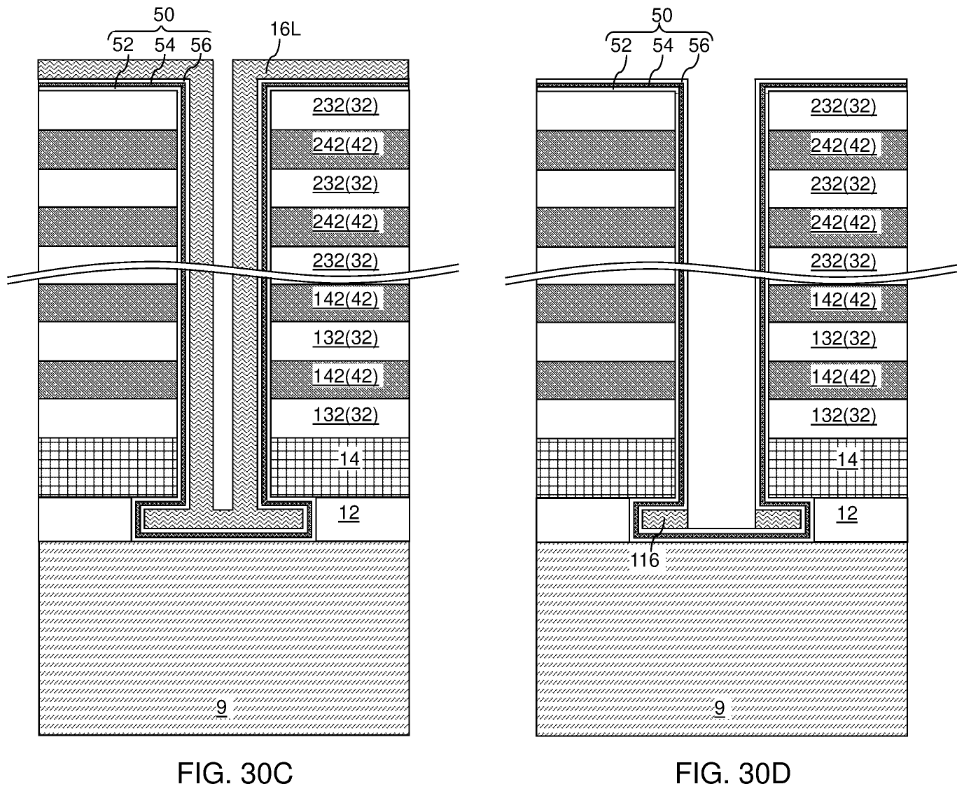

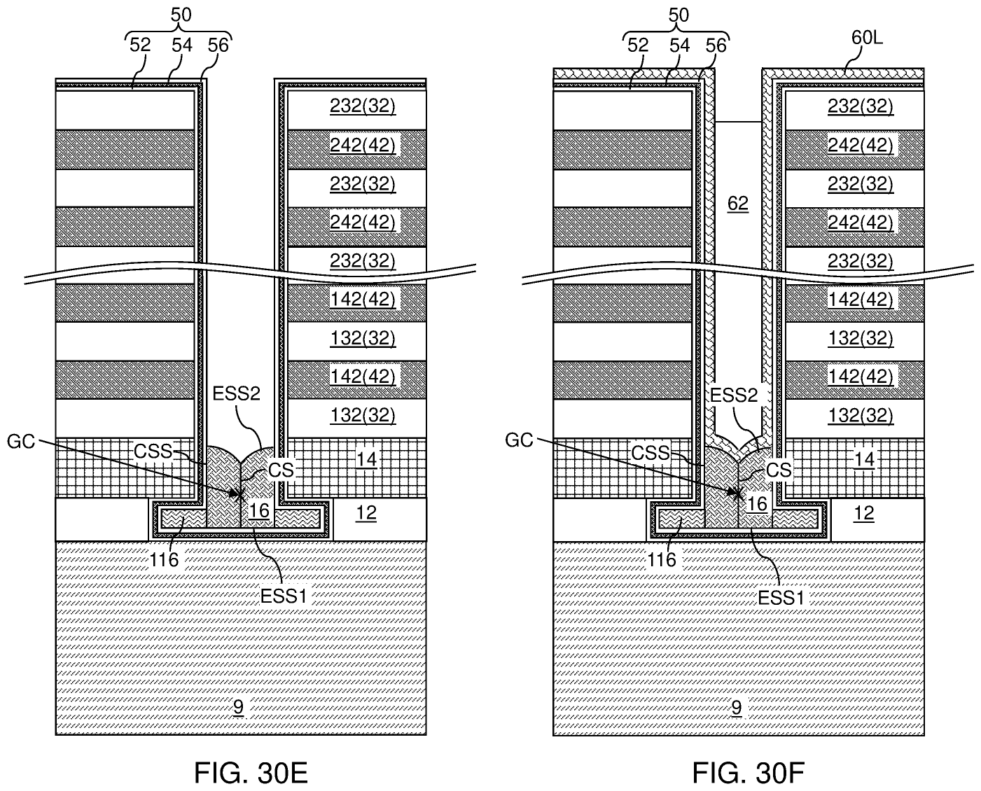

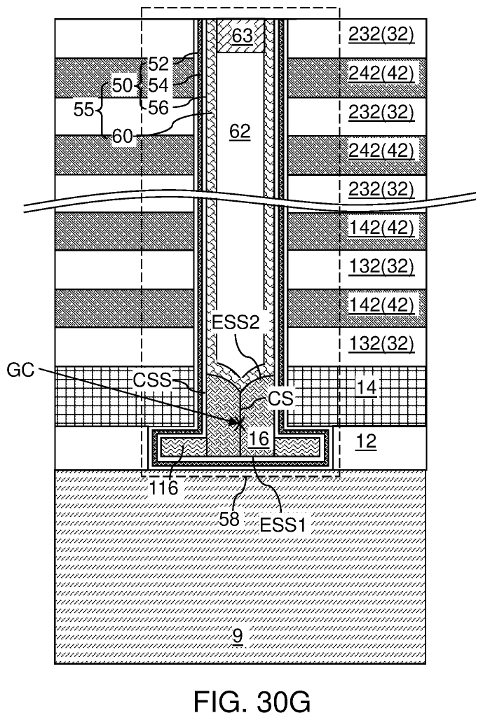

FIGS. 30A-30G are sequential vertical cross-sectional views of a memory opening 49 during formation of a memory opening fill structure 58 in the second exemplary structure according to the second embodiment of the present disclosure.

Referring to FIG. 30A, a memory opening 49 in the second exemplary structure is illustrated, which comprises the annular recess cavity 13 located at the level of the backside stopper layer 12. The annular recess cavity 13 is formed around each memory opening 49 at the level of the backside stopper layer 12 by removal of the sacrificial pedestal structure 348.

Referring to FIG. 30B, the processing steps described with reference to FIG. 9B can be performed to form a memory film 50 within at peripheral portions of the memory openings 49, and over the topmost surface of the alternating stack {(132, 142), (232, 242)}.

Referring to FIG. 30C, the processing steps described with reference to FIG. 9C can be performed to form a conformal doped semiconductor layer 16L including a doped semiconductor fill material. The doped semiconductor fill material has a doping of a second conductivity type, which is the opposite of the first conductivity type of vertical semiconductor channels to be subsequently formed. If the first conductivity type is p-type, the second conductivity type is n-type, and vice versa. The atomic concentration of dopants of the second conductivity type in the doped semiconductor fill material may be in a range form 1.0×10¹⁴/cm³ to 1.0×10²¹/cm³, such as from 1.0×10¹⁶/cm³ to 1.0×10²⁰/cm³, although lesser and greater atomic concentrations may also be employed. The thickness of the conformal doped semiconductor layer 16L may be less than one half of the diameter of each memory opening 49, and may be greater than one half of the difference between the thickness of the backside stopper layer 12 and twice the thickness of the memory film 50. The entire volume of each annular recess cavity 13 may be filled with materials of the memory film 50 and the conformal doped semiconductor layer 16L. A cylindrical cavity may be present within each memory opening 49.

Referring to FIG. 30D, an etch back process can be performed to remove portions of the conformal doped semiconductor layer 16L outside the annular recess cavities 13, such as portions which overlie the horizontal plane including the top surface of the backside stopper layer 12 or are not masked by the combination of the alternating stack {(132, 142), (232, 242)} and vertically-extending portions of the memory film 50 that are laterally surrounded by the alternating stack {(132, 142), (232, 242)}. Each remaining portion of the conformal doped semiconductor layer 16L having a respective annular shape and underlies the source-side spacer layer 14 constitutes an annular semiconductor ring 116. Each annular semiconductor ring 116 may be formed inside a respective annular recess cavity 13 defined by a respective portion of the memory film 50 that underlies the source-side spacer layer 14. Each annular semiconductor ring 116 may have an inner cylindrical surface that is vertically coincident with an inner cylindrical sidewall of a vertically-extending portion of the memory film 50.

Referring to FIG. 30E, a selective semiconductor deposition process can be performed to grow a doped semiconductor material having a doping of the second conductivity type from physically exposed cylindrical surfaces of the annular semiconductor rings 116 while suppressing growth of the doped semiconductor material from physically exposed dielectric surfaces such as the physically exposed surfaces of the memory film 50, i.e., from the physically exposed surfaces of the dielectric liner 56 (which may be a tunneling dielectric layer). A selective deposition process refers to a deposition process in which a material is grown from a first-type surface while deposition of the material from a second-type surface is suppressed. A selective semiconductor deposition process refers to a deposition process in which a semiconductor material is grown from a first-type surface such as a physically exposed semiconductor surface while deposition of the semiconductor material from a second-type surface such as an insulating surface is suppressed.

The selective semiconductor deposition process forms the source cap structure 16 on an inner sidewall of each annular semiconductor ring 116. The duration of the selective semiconductor deposition process can be selected such that growth surfaces of the semiconductor material of the source cap structure 16 merge at a center portion to form a center seam CS. In one embodiment, the vertical extent of each center seam CS may be greater than the height of each annular semiconductor ring 116.

According to an aspect of the present disclosure, the selective semiconductor deposition process may be performed with in-situ doping with dopants of the second conductivity type. The atomic concentration of dopants of the second conductivity type in the source cap structures 16 may be in a range from 5.0×10¹⁸/cm³ to 2.0×10²¹/cm³, such as from 1.0×10²⁰/cm³ to 1.0×10²¹/cm³, although lesser and greater atomic concentrations may also be employed. In an illustrative example, if the vertical semiconductor channels to be subsequently formed are doped with p-type dopants (such as boron), the source cap structures 16 are doped with n-type dopants (such as phosphorus). The source cap structures 16 form p-n junctions with respect to vertical semiconductor channels to be subsequently formed, and thus, function as components of source structures. Control of the duration of the selective semiconductor deposition process allows control of the location of the top surfaces of the source cap structures 16, and thus, allows control of the height of the p-n junctions to be subsequently formed.

In one embodiment, each source cap structure 16 may comprise a center seam CS that vertically extends from a center of a top surface thereof to a center of a bottom surface thereof. In one embodiment, each source cap structure 16 comprises a contoured top surface having a periphery that is raised above a center point of the contoured top surface. In one embodiment, the contoured top surface of each source cap structure 16 comprises convex surface, while the bottom surface of each source cap structure 16 is flat. In one embodiment, the geometrical center GC of each source cap structure 16 can be located at a point within a center seam CS of the source cap structure 16. As used herein, a geometrical center of an object is the location of the center of gravity of a hypothetical object that occupies the same volume as the object and having a uniform density throughout.

Each source cap structure 16 may comprise a cylindrical surface segment CSS that continuously extends from a first end surface segment ESS1 contacting a top surface of a horizontally-extending portion of the memory film 50 to a second end surface segment ESS2 that is physically exposed to a cavity located within a respective memory opening 49. In one embodiment, a first (i.e., lower) cylindrical area of the cylindrical surface segment CSS of each source cap structure 16 may contact a respective annular semiconductor ring 116. A second (i.e., upper) cylindrical area of the cylindrical surface segment CSS of each source cap structure 16 may contact a cylindrical surface segment of an inner sidewall of the memory film 50.

The first end surface segment ESS1 is adjoined to a first periphery of the cylindrical surface segment CSS. The second end surface segment ESS2 is adjoined to a second periphery of the cylindrical surface segment CSS. In one embodiment, the second end surface segment ESS2 comprises a convex surface segment having a lowest point that is adjoined to a topmost point of the central seam CS. In one embodiment, each source cap structure 16 has a variable thickness that varies along a radial direction from a vertical axis passing through the geometrical center GC of the source cap structure 16. In one embodiment, each source cap structure 16 comprises a central seam CS that vertically extends from the first end surface segment ESS1 to a second end surface segment ESS2 that is adjoined to a second periphery of the cylindrical surface segment.

Referring to FIG. 30F, a semiconductor channel material layer 60L can be deposited on the memory film 50 and each of the source cap structures 16 by performing a conformal deposition process. In one embodiment, the semiconductor channel material layer 60L may be doped with dopants of the first conductivity type, which is the opposite of the second conductivity type. The atomic concentration of dopants of the first conductivity type in the semiconductor channel material layer 60L may be in a range from 1.0×10¹²/cm³ to 3.0×10¹⁷/cm³, such as from 1.0×10¹⁴/cm³ to 3.0×10¹⁶/cm³, although lesser and greater atomic concentrations may also be employed. The thickness of the semiconductor channel material layer 60L may be in a range from 3 nm to 60 nm, such as from 6 nm to 30 nm, although lesser and greater thicknesses may also be employed. In one embodiment, each portion of the semiconductor channel material layer 60L located within a respective memory opening 49 may comprise a contoured bottom surface which is a concave surface that contacts the convex surface of the source cap structure 16. A p-n junction can be formed at each interface between the semiconductor channel material layer 60L and each of the source cap structures 16.

A dielectric core layer comprising a dielectric fill material, such as silicon oxide, can be deposited in remaining volumes of the memory openings 49. The dielectric core layer can be vertically recessed such that each remaining portion of the dielectric core layer has a top surface at, or about, the horizontal plane including the bottom surface of a topmost insulating layers 32. Each remaining portion of the dielectric core layer constitutes a dielectric core 62.

Referring to FIG. 30G, a doped semiconductor material having a doping of the second conductivity type can be deposited within each recessed region above the dielectric cores 62. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon. Excess portions of the deposited semiconductor material having a doping of the second conductivity type, a horizontally-extending portion of the semiconductor channel material layer 60L, and a horizontally-extending potion of the memory film 50 can be removed from above the horizontal plane including the top surface of the topmost layer of the alternating stack (32, 42), for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each contiguous combination of a memory film 50 and a vertical semiconductor channel 60 constitutes a memory stack structure 55. The set of all material portions that fills a contiguous combination of a memory opening 49 constitutes a memory opening fill structure 58. Each memory opening fill structure 58 can be located in a memory opening 49, and can comprise an annular semiconductor ring 116, a source cap structure 16, a memory film 50, a vertical semiconductor channel 60, a dielectric core 62, and a drain region 63. In one embodiment, each source cap structure 16 comprises a second end surface segment ESS2 having a convex surface segment that contacts a concave surface segment of a vertical semiconductor channel 60.

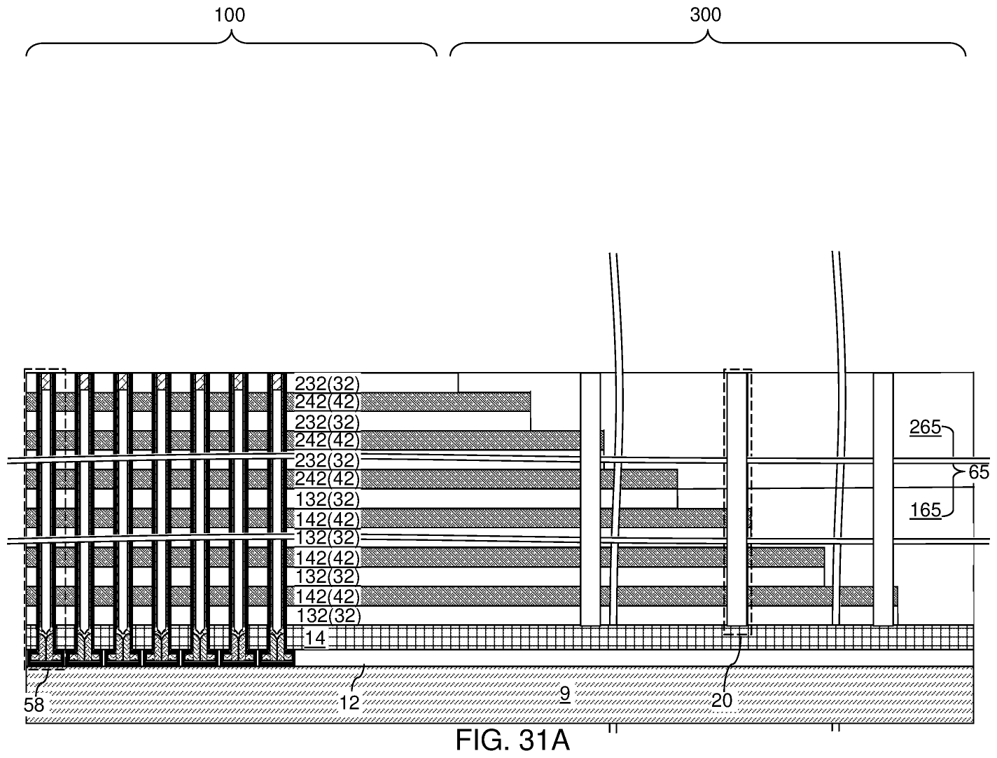

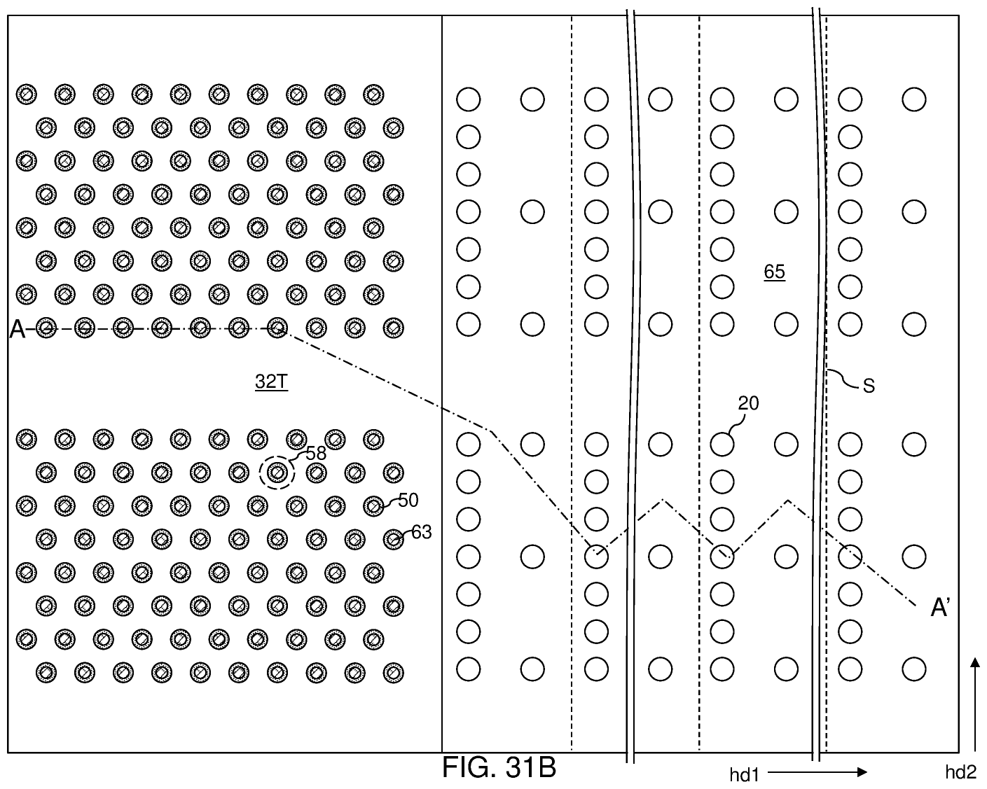

Referring to FIGS. 31A and 31B, the second exemplary structure is illustrated after formation of memory opening fill structures 58 within the memory openings 49 and formation of the support pillar structures 20 in the support openings 19. Each of the support pillar structures 20 may comprise a memory film 50, a vertical semiconductor channel 60, a dielectric core 62, and a drain region 63. The support pillar structures 20 may be free of any semiconductor material having a doping of the second conductivity type and may consist essentially of an insulating material.

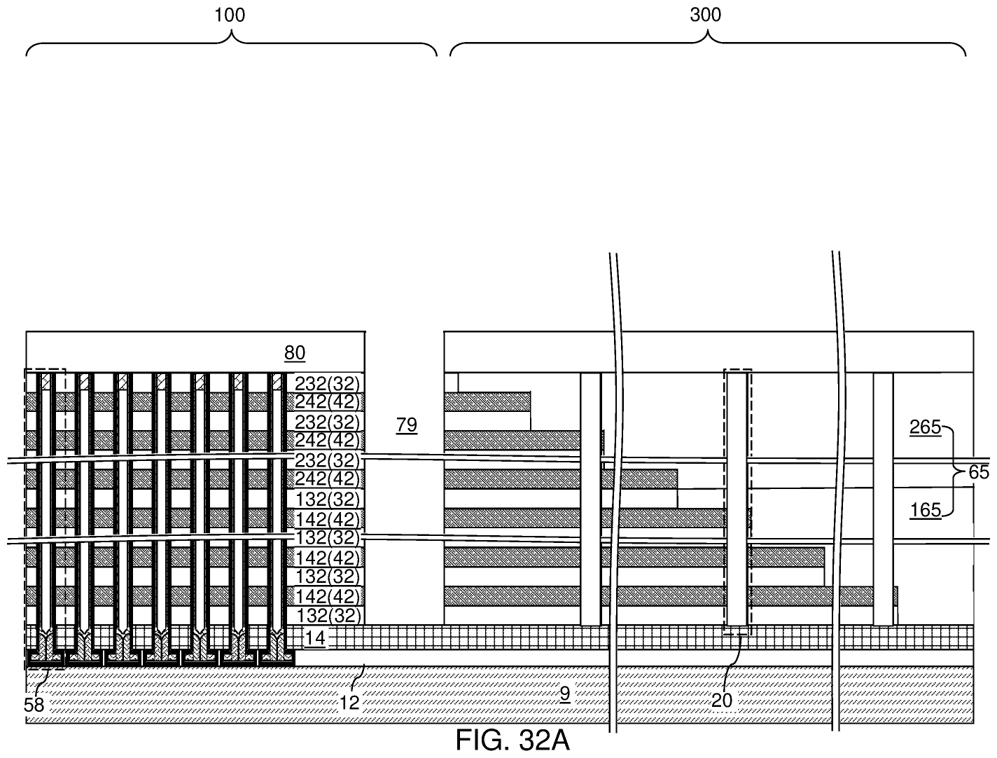

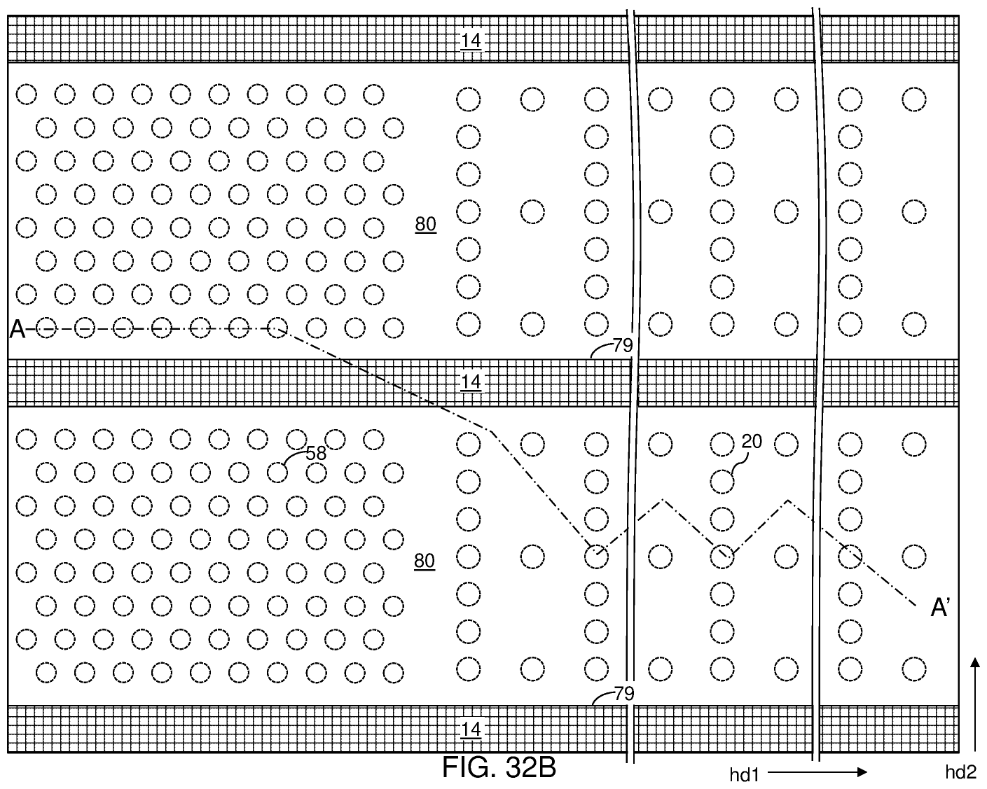

Referring to FIGS. 32A and 32B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and at least to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the carrier substrate 9 to the top surface of the contact-level dielectric layer 80. A surface of the carrier substrate 9 can be physically exposed underneath each lateral isolation trench 79. The photoresist layer can be subsequently removed, for example, by ashing.

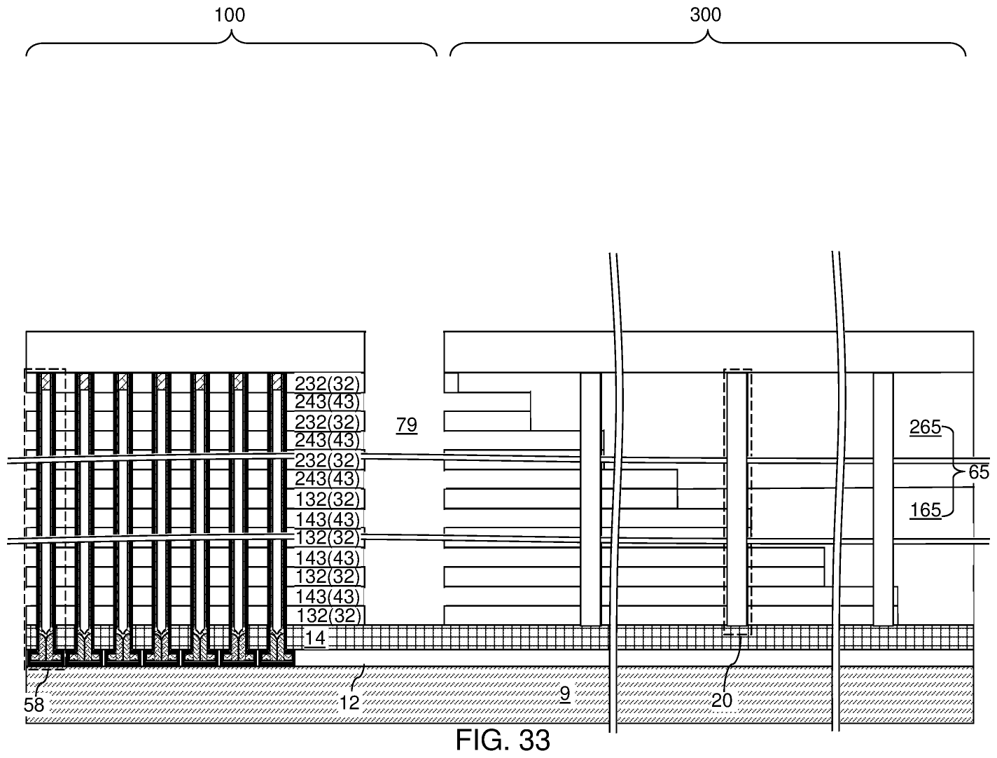

Referring to FIG. 33, the step described above with respect to FIG. 12 is performed to form the lateral recesses 43. Specifically, an etchant that selectively etches the material of the sacrificial material layers 42 with respect to the material of the insulating layers 32, the source-side spacer layer 14, and the carrier substrate 9 can be introduced into the lateral isolation trenches 79, for example, employing an isotropic etch process. Lateral recesses 43 are formed in volumes from which the sacrificial material layers 42 are removed.

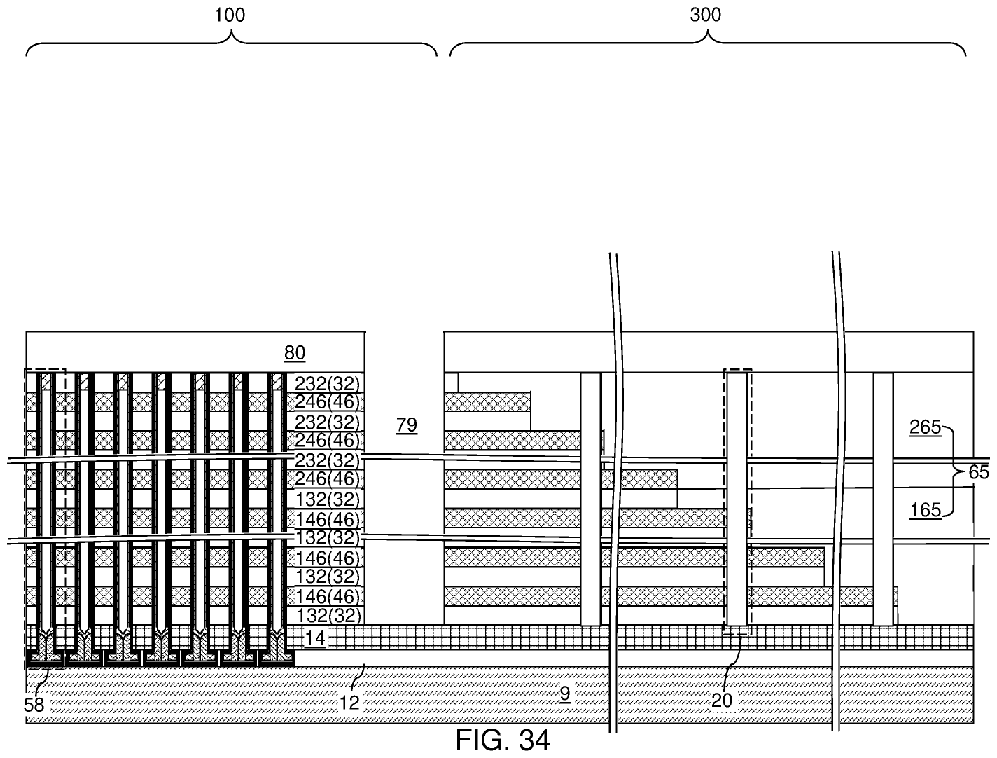

Referring to FIG. 34, an outer blocking dielectric layer (not expressly illustrated in FIG. 34) can be optionally formed, as described above with respect to FIG. 13. The electrically conductive layers 46 are then formed in the lateral recesses 43, as described above with respect to FIG. 13. At least one uppermost electrically conductive layer 46 may comprise a respective drain-side select gate electrode. At least one bottommost electrically conductive layer 46 may comprise a respective source-side select gate electrode. The remaining electrically conductive layers 46 may comprise word lines. Each word line functions as a common control gate electrode for the plurality of vertical NAND strings (e.g., memory opening fill structures 58).

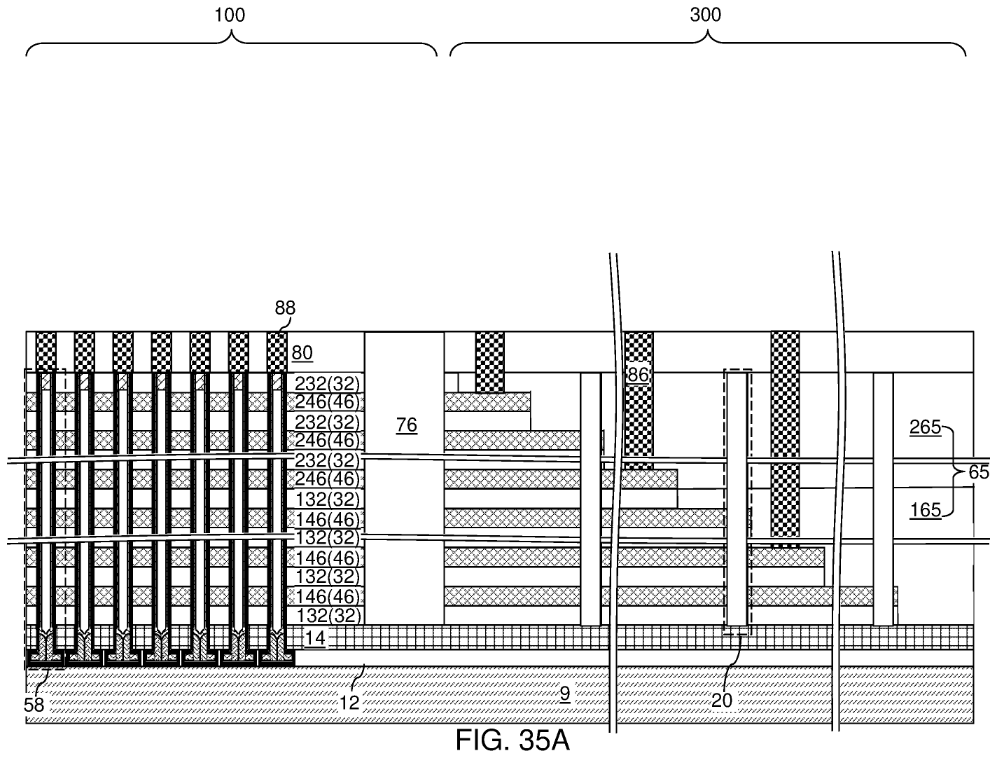

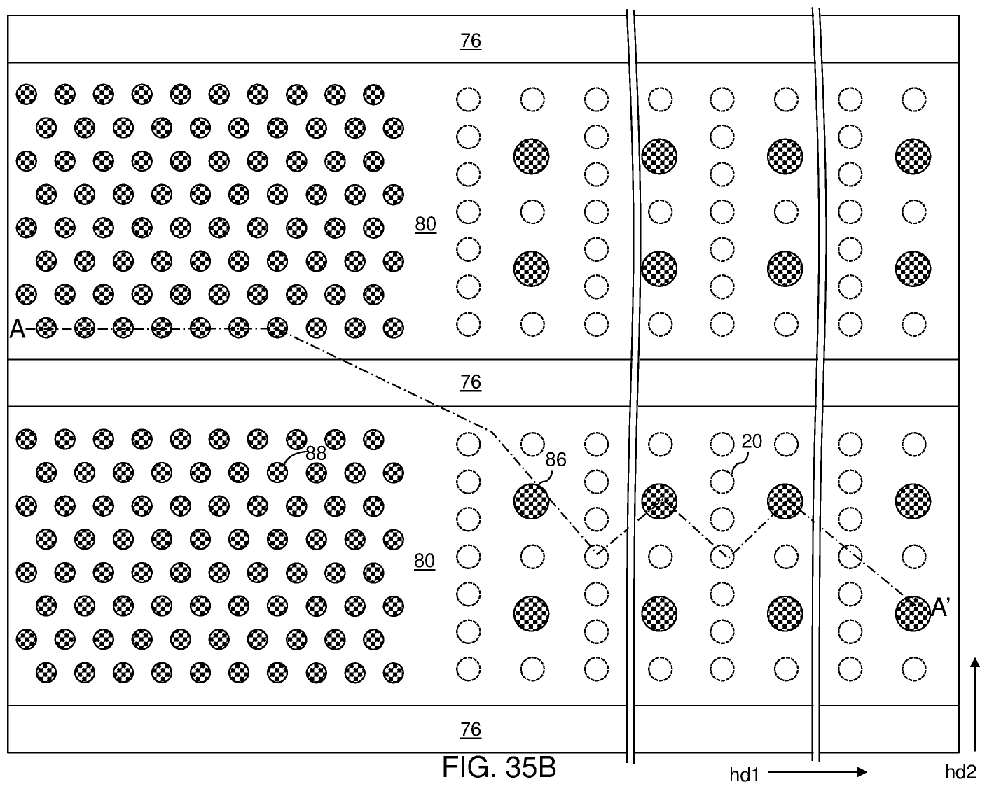

Referring to FIGS. 35A and 35B, the steps described above with respect to FIGS. 14A and 14B are performed to form the lateral isolation trench fill structure 76 in the lateral isolation trenches 79 and to form the contact via structures (88, 86).

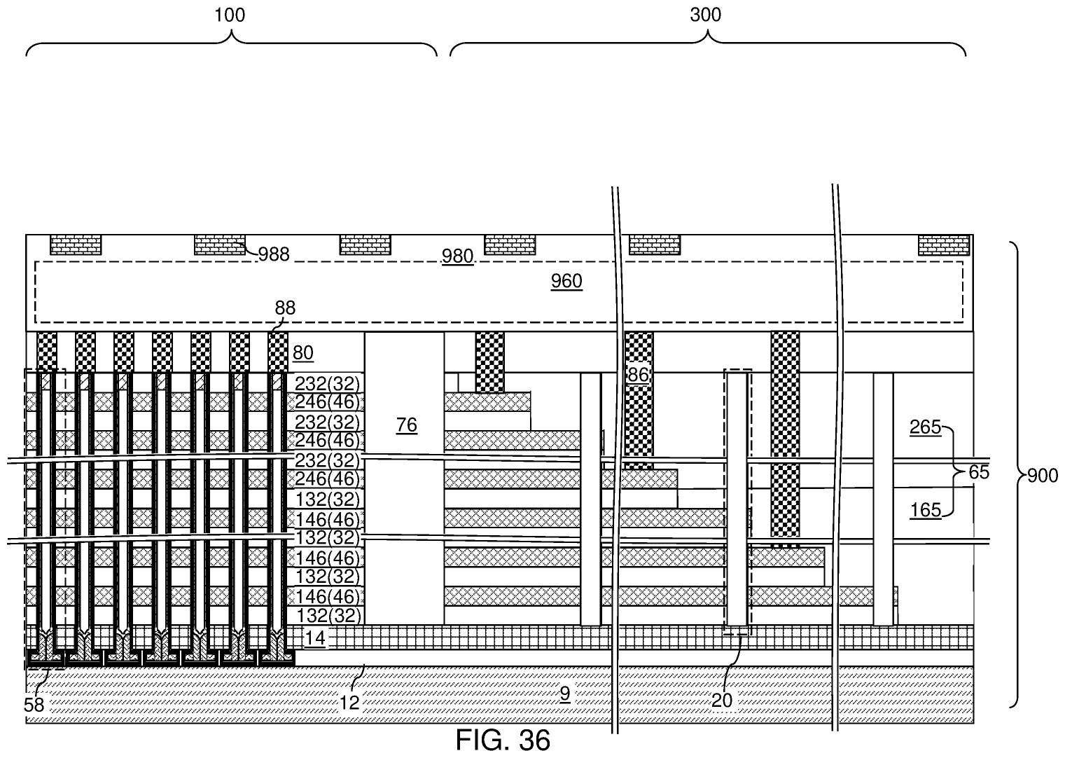

Referring to FIG. 36, the steps described above with respect to FIG. 15 are performed to form the memory-side dielectric material layers 960, memory-side metal interconnect structures 980 and the memory-side bonding pads 988,

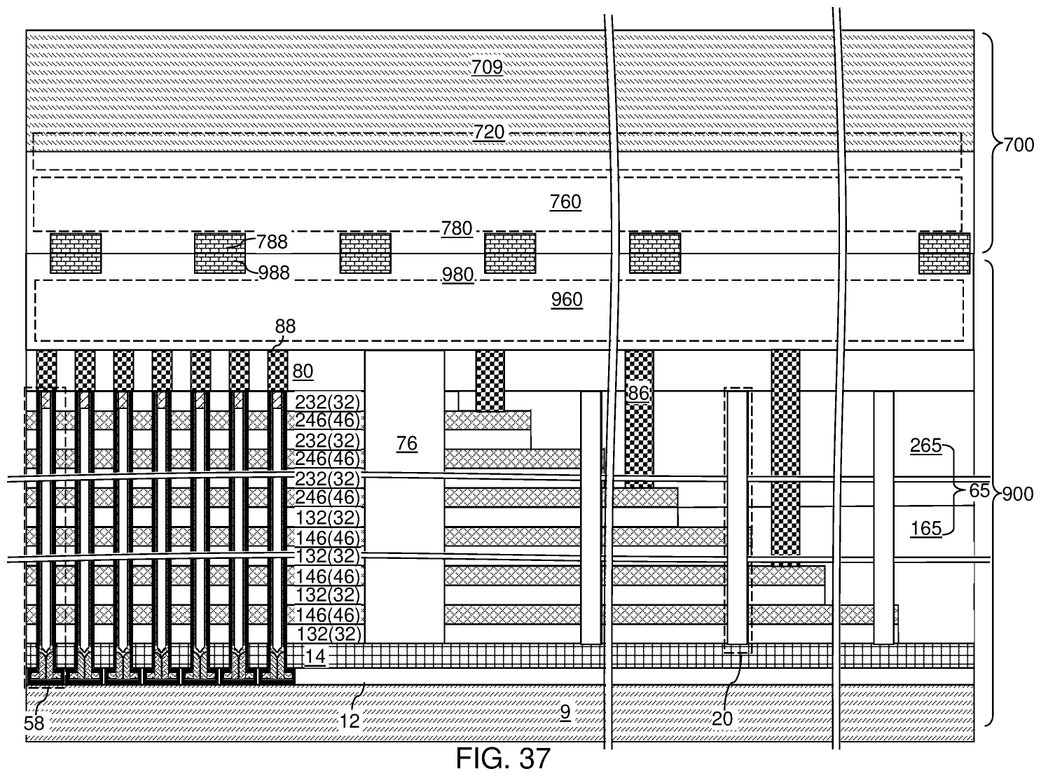

Referring to FIG. 37, the logic die 700 can be attached to the memory die 900, for example, by bonding the logic-side bonding pads 788 to the memory-side bonding pads 988 at a bonding interface, as described with reference to FIG. 17. The logic die 700 in the second exemplary structure may be the same as the logic die 700 described with reference to FIG. 16.

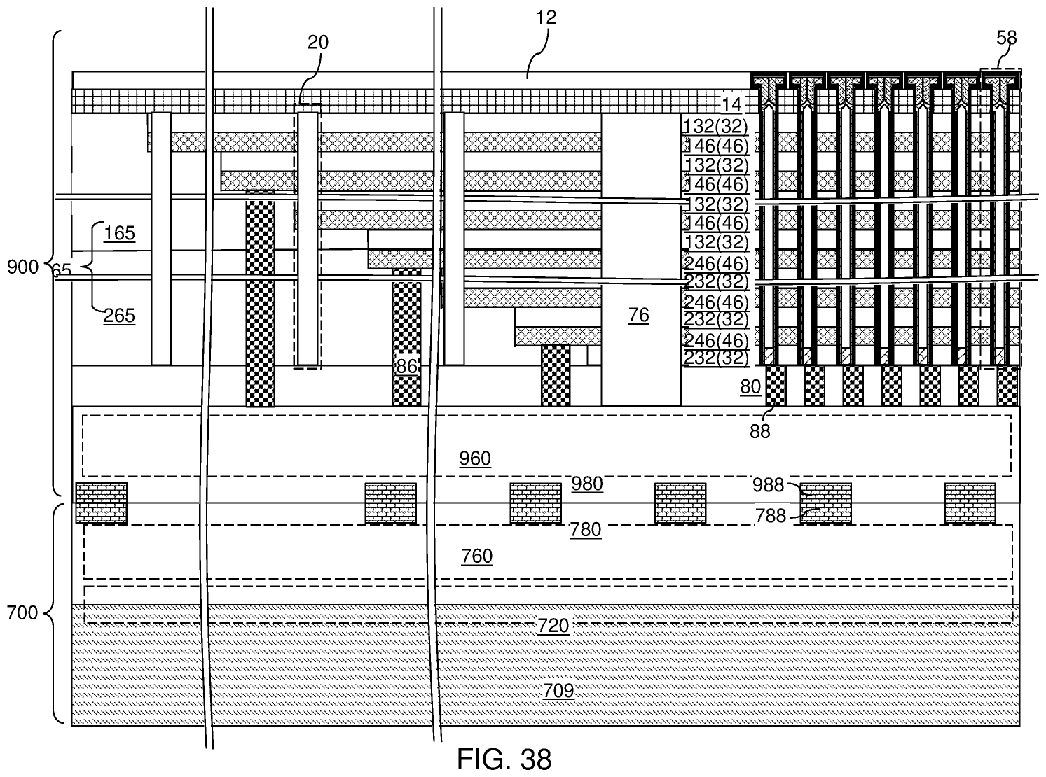

Referring to FIG. 38, the carrier substrate 9 can be removed, for example, by grinding, polishing, cleaving, an isotropic etch process, and/or an anisotropic etch process, as described above with reference to FIG. 18.

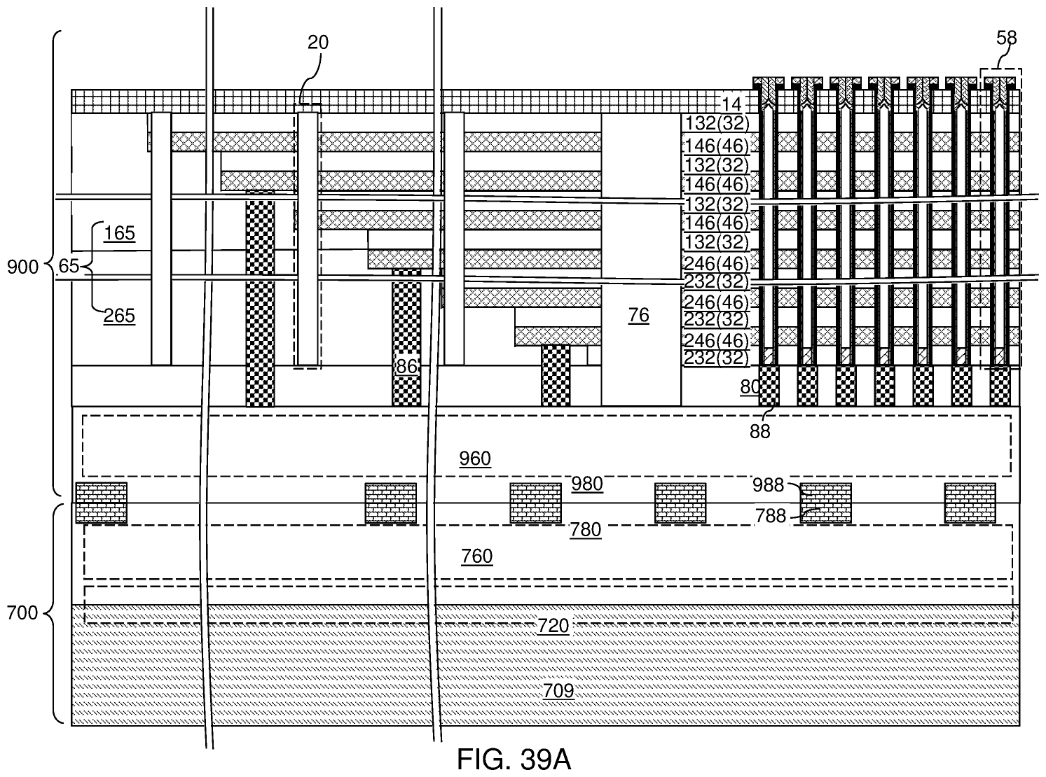

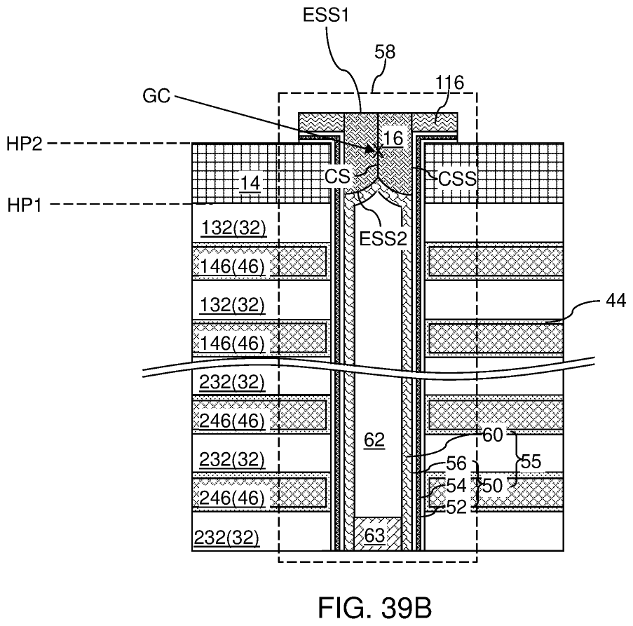

Referring to FIGS. 39A and 39B, the backside stopper layer 12 and end portions of the memory films 50 can be removed by performing a sequence of etch processes, as described above with respect to FIGS. 19A and 19B.

In an illustrative example, a first etch process that etches the material of the backside stopper layer 12 can be performed. If the backside stopper layer 12 comprises silicon oxide, a wet etch process employing dilute hydrofluoric acid can be employed as the first etch process to remove the backside stopper layer 12 selective to the material of the source-side spacer layer 14 (which may comprise a semiconductor material such as polysilicon) and selective to the material of the memory material layer 54. If the blocking dielectric layers 52 comprise silicon oxide, portions of the blocking dielectric layers 52 that are not masked by the annular semiconductor rings 116 may be collaterally removed during the first etch process.

Subsequently, a second etch process can be performed to remove portions of the memory material layers 54 that are not masked by the annular semiconductor rings 116 selective to the material of the dielectric liner 56 and the source-side spacer layer 14. If the memory material layers 54 comprise silicon nitride, a wet etch process employing hot phosphoric acid or a mixture of dilute hydrofluoric acid and ethylene glycol can be employed as the second etch process to remove end portions of the memory material layers 54 that are exposed to voids in the openings in the source-side spacer layer 14.

Further, a third etch process can be performed to remove portions of the dielectric liners 56 that are not masked by the annular semiconductor rings 116 selective to the material of the annular semiconductor rings 116, the source cap structures 16, and the source-side spacer layer 14. If the dielectric liners 56 comprise silicon oxide and/or silicon oxynitride, a wet etch process employing dilute hydrofluoric acid or another suitable etchant solution can be employed as the third etch process to remove end portions of the dielectric liners 56 that are not masked by the annular semiconductor rings 116.

A first end surface segment ESS1 of each source cap structure 16 can be physically exposed after the sequence of etch processes. Each source cap structure 16 may comprise a first end surface segment ESS1 that is physically exposed. Each annular semiconductor ring 116 may comprise a respective annular surface and a respective cylindrical surface that are exposed. Each memory film 50 in a memory opening fill structure 58 may comprise a respective annular portion that is interposed between the source-side spacer layer 14 and the annular semiconductor ring 116. Generally, the first end surface segment ESS1 of each source cap structure 16, an edge portion of each memory film 50, and a backside surface of the source-side spacer layer 14 can be physically exposed upon removal of the backside stopper layer 12 and end portions of the memory films 50.

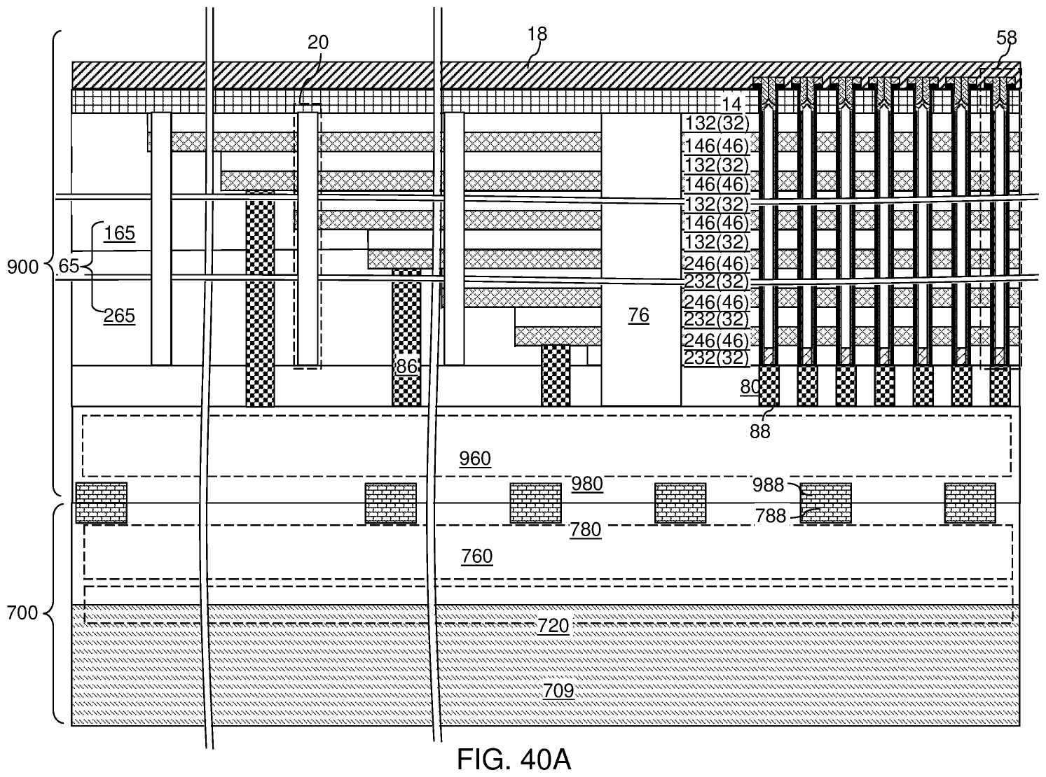

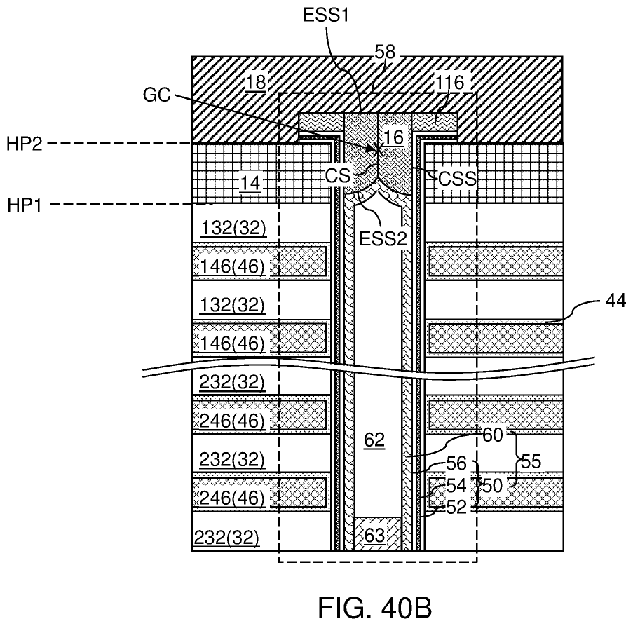

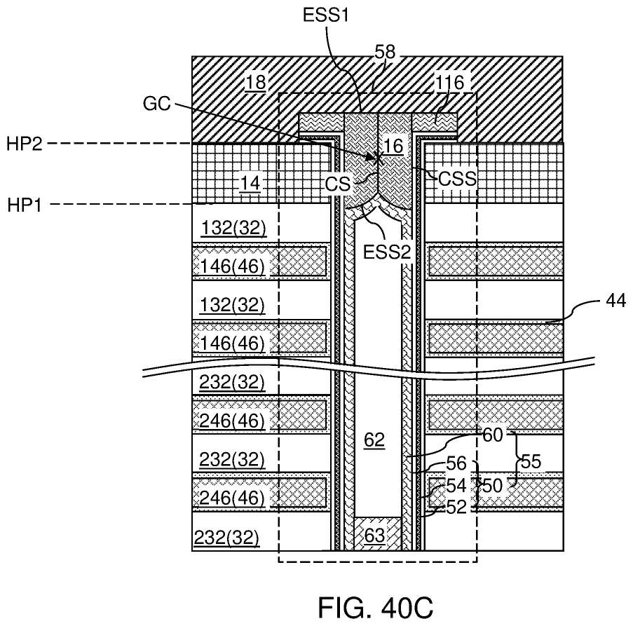

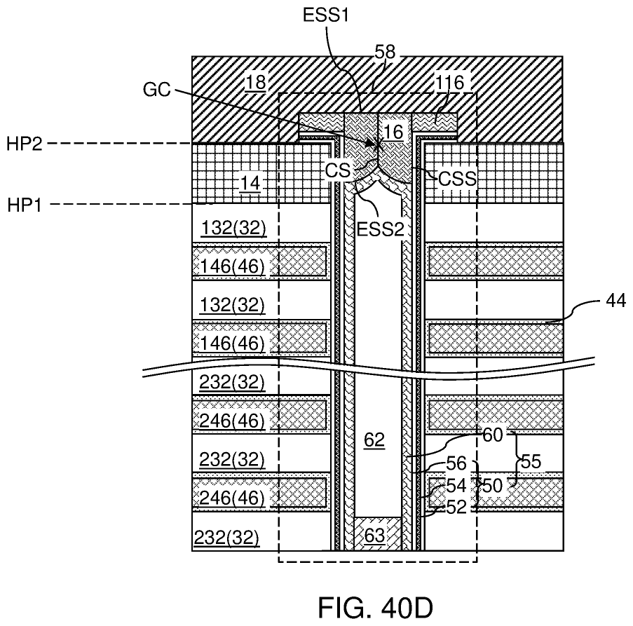

Referring to FIGS. 40A and 40B, a source layer 18 can be formed by depositing at least one metallic material on the physically exposed planar backside surface of the source-side spacer layer 14 and on the physically exposed surfaces of the annular semiconductor rings 116 and the source cap structure 16. The source layer 18 may comprise a stack of an optional metallic barrier material (such as TIN, TaN, WN, MoN, TiC, TaC, WC, etc.) and a high-electrical-conductivity metal material (such as Cu, Mo, W, Ti, Ta, Co, Ru, etc.). The source layer 18 can be formed on a bottom surface of the source-side spacer layer 14 and on exposed cylindrical sidewalls of remaining portions of the memory films 50 after removal of the physically exposed portion of the memory film 50. The source layer 18 contacts the first end surface segment ESS1 of each source cap structure 16 and the annular semiconductor ring 116.

In one embodiment, the entirety of the second end surface segment ESS2 of each source cap structure 16 may be located between a first horizontal plane HP1 including a first horizontal surface (such as a top surface) of the source-side spacer layer 14 and a second horizontal plane HP2 including a second horizontal surface (such as a bottom surface) of the source-side spacer layer 14. Generally, the location of the p-n junction between a source cap structure 16 and a vertical semiconductor channel 60 may be adjusted as need. FIG. 40C illustrates a configuration in which at least a portion of the second end surface segment ESS2 of each source cap structure 16 is more distal from the horizontal plane (such as the second horizontal plane HP2) including an interface between the source-side spacer layer 14 and the source layer 18 than the alternating stack {(132, 146), (232, 246)} is from the horizontal plane. FIG. 40D illustrates a configuration in which the second end surface segment ESS2 of each source cap structure 16 is more proximal to the horizontal plane (such as the second horizontal plane HP2) including an interface between the source-side spacer layer 14 and the source layer 18 than in the configuration illustrated in FIG. 40B.

The embodiments of the present disclosure include a semiconductor structure which comprises: an alternating stack {(132, 146), (232, 246)} of insulating layers (132, 232) and electrically conductive layers (146, 246); a memory opening 49 vertically extending through the alternating stack {(132, 146), (232, 246)}; a memory opening fill structure 58 located in the memory opening 49 and comprising a memory film 50, a vertical semiconductor channel 60, and a semiconductor source cap structure 16 which is at least partially laterally surrounded by the memory film 50 and which contacts the vertical semiconductor channel 60, and a source layer 18 contacting at least a first end surface segment ESS1 of the source cap structure 16.

In some embodiments, the semiconductor structure further comprises a source-side spacer layer 14 located between the source layer 18 and the alternating stack {(132, 146), (232, 246)}. The memory opening 49 also vertically extends through the source-side spacer layer 14; and the semiconductor source cap structure 16 is laterally surrounded by the source-side spacer layer 14. The vertical semiconductor channel 60 has a doping of a first conductivity type; The source-side spacer layer 14 comprises a semiconductor material layer; the semiconductor source cap structure 16 comprises a semiconductor material having a doping of a second conductivity type that is an opposite of the first conductivity type; a first end of the vertical semiconductor channel 60 contacts the semiconductor source cap structure 16; and the memory opening fill structure 58 further comprises a drain region 63 having a doping of the second conductivity type and contacting a second end of the vertical semiconductor channel 60 opposite to the first end.

In the first embodiment, the semiconductor source cap structure 16 further comprises an annular conical surface segment ACSS adjoined to the first end surface segment ESS1; and the annular conical surface segment ACSS is laterally surrounded by the memory film 50 and by the source-side spacer layer 14.

In the first embodiment, the annular conical surface segment ACSS comprises: a first tapered annular area in contact with the source layer 18; and a second tapered annular area in contact with the memory film 50. In the first embodiment, the semiconductor source cap structure 16 comprises a second end surface segment ESS2 that contacts a convex end surface of the vertical semiconductor channel 60. In the first embodiment, the second end surface segment ESS2 comprises a convex surface segment located entirely between a first horizontal plane HP1 including a first horizontal surface of the source-side spacer layer 14 and a second horizontal plane HP2 including a second horizontal surface of the source-side spacer layer 14.

In the first embodiment, the source-side spacer layer 14 comprises an opening having a tapered conical sidewall TCS; and the tapered conical sidewall TCS comprises a first tapered conical surface segment that contacts a conical surface segment of the source layer 18. In the first embodiment, a lateral extent of the opening in the source-side spacer layer 14 increases with a vertical distance from a horizontal plane including an interface between the source-side spacer layer 14 and the source layer 18 toward the alternating stack {(132, 146), (232, 246)}. In the first embodiment, the tapered conical sidewall TCS comprises a second tapered conical surface segment that contacts a conical surface segment of an outer sidewall of the memory film 50.

In the second embodiment, the semiconductor source cap structure 16 further comprises a cylindrical surface segment CSS. The first end surface segment ESS1 is adjoined to a first periphery of the cylindrical surface segment CSS.

In the second embodiment, the semiconductor structure further comprises an annular semiconductor ring 116 having an inner cylindrical surface that contacts a first cylindrical area of the cylindrical surface segment of the semiconductor source cap structure 16. In the second embodiment, a second cylindrical area of the cylindrical surface segment of the source cap structure 16 contacts a cylindrical surface segment of an inner sidewall of the memory film 50. In the second embodiment, the memory film 50 comprises an annular plate portion that is interposed between the source-side spacer layer 14 and the annular semiconductor ring 116.

In the second embodiment, the semiconductor source cap structure 16 further comprises second end surface segment ESS2 that is adjoined to a second periphery of the cylindrical surface segment; and the second end surface segment ESS2 comprises a convex surface segment that contacts a concave surface segment of the vertical semiconductor channel 60. In the second embodiment, the semiconductor source cap structure 16 has a variable thickness that varies along a radial direction from a vertical axis passing through a geometrical center GC of the semiconductor source cap structure 16; and the semiconductor source cap structure 16 comprises a central seam CS that vertically extends from the first end surface segment ESS1 to a second end surface segment ESS2 that is adjoined to a second periphery of the cylindrical surface segment.

The various embodiments of the present disclosure may be employed to provide a high quality Ohmic electrical contact between a source layer 18 and source cap structure 16. Further, the various embodiments of the present disclosure may be employed to provide enhanced control over locations of p-n junctions by adjusting locations of a second end surface segment ESS2 of each source cap structure 16 relative to that of the vertical semiconductor channel 60.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
an alternating stack of insulating layers and electrically conductive layers;
a memory opening vertically extending through the alternating stack;
a memory opening fill structure located in the memory opening and comprising a memory film, a vertical semiconductor channel, and a semiconductor source cap structure which is at least partially laterally surrounded by the memory film and which contacts the vertical semiconductor channel; and
a source layer contacting at least a first end surface segment of the semiconductor source cap structure.

2. The semiconductor structure of claim 1, further comprising a source-side spacer layer located between the source layer and the alternating stack, wherein:
the memory opening also vertically extends through the source-side spacer layer; and
the semiconductor source cap structure is laterally surrounded by the source-side spacer layer.

3. The semiconductor structure of claim 2, wherein:
the semiconductor source cap structure further comprises an annular conical surface segment adjoined to the first end surface segment; and
the annular conical surface segment is laterally surrounded by the memory film and by the source-side spacer layer.

4. The semiconductor structure of claim 3, wherein the annular conical surface segment comprises:
a first tapered annular area in contact with the source layer; and
a second tapered annular area in contact with the memory film.

5. The semiconductor structure of claim 3, wherein the semiconductor source cap structure further comprises a second end surface segment that contacts a convex end surface of the vertical semiconductor channel.

6. The semiconductor structure of claim 5, wherein the second end surface segment comprises a convex surface segment located entirely between a first horizontal plane including a first horizontal surface of the source-side spacer layer and a second horizontal plane including a second horizontal surface of the source-side spacer layer.

7. The semiconductor structure of claim 3, wherein:
the source-side spacer layer comprises an opening having a tapered conical sidewall; and
the tapered conical sidewall comprises a first tapered conical surface segment that contacts a conical surface segment of the source layer.

8. The semiconductor structure of claim 7, wherein a lateral extent of the opening in the source-side spacer layer increases with a vertical distance from a horizontal plane including an interface between the source-side spacer layer and the source layer toward the alternating stack.

9. The semiconductor structure of claim 7, wherein the tapered conical sidewall comprises a second tapered conical surface segment that contacts a conical surface segment of an outer sidewall of the memory film.

10. The semiconductor structure of claim 2, wherein:
the semiconductor source cap structure further comprises a cylindrical surface segment; and
the first end surface segment is adjoined to a first periphery of the cylindrical surface segment.

11. The semiconductor structure of claim 10, further comprising an annular semiconductor ring having an inner cylindrical surface that contacts a first cylindrical area of the cylindrical surface segment of the semiconductor source cap structure.

12. The semiconductor structure of claim 11, wherein:
a second cylindrical area of the cylindrical surface segment of the semiconductor source cap structure contacts a cylindrical surface segment of an inner sidewall of the memory film; and
the memory film comprises an annular plate portion that is interposed between the source-side spacer layer and the annular semiconductor ring.

13. The semiconductor structure of claim 10, wherein:
the semiconductor source cap structure further comprises second end surface segment that is adjoined to a second periphery of the cylindrical surface segment; and
the second end surface segment comprises a convex surface segment that contacts a concave surface segment of the vertical semiconductor channel.

14. The semiconductor structure of claim 10, wherein:
the semiconductor source cap structure has a variable thickness that varies along a radial direction from a vertical axis passing through a geometrical center of the semiconductor source cap structure; and
the semiconductor source cap structure further comprises a central seam that vertically extends from the first end surface segment to a second end surface segment that is adjoined to a second periphery of the cylindrical surface segment.

15. The semiconductor structure of claim 2, wherein:
the vertical semiconductor channel has a doping of a first conductivity type;
the source-side spacer layer comprises a semiconductor material layer;
the semiconductor source cap structure comprises a semiconductor material having a doping of a second conductivity type that is an opposite of the first conductivity type;
a first end of the vertical semiconductor channel contacts the semiconductor source cap structure; and
the memory opening fill structure further comprises a drain region having a doping of the second conductivity type and contacting a second end of the vertical semiconductor channel opposite to the first end.

16. A method of forming a semiconductor structure, comprising:
forming a source-side spacer layer over a carrier substrate;
forming an alternating stack of insulating layers and spacer material layers over the source-side spacer layer, wherein the spacer material layers are formed as or are subsequently replaced with electrically conductive layers;
forming a memory opening through the alternating stack and the source-side spacer layer;
forming a memory film at a peripheral portion of the memory opening;
forming a semiconductor source cap structure at a bottom portion of the memory film;
forming a vertical semiconductor channel on a top surface of the semiconductor source cap structure and on an inner sidewall of the memory film;
removing the carrier substrate; and
forming a source layer on an exposed bottom surface segment of the semiconductor source cap structure.

17. The method of claim 16, wherein:
the memory opening comprises a bottom cavity portion having a shape of an inverted cone or an inverted conical frustum; and
the semiconductor source cap structure is formed by conformally depositing and isotropically etching a doped semiconductor material, wherein a remaining portion of the doped semiconductor material comprises the semiconductor source cap structure.

18. The method of claim 16, wherein:
the vertical semiconductor channel comprises dopants of a first conductivity type at a first atomic concentration; and
the semiconductor source cap structure comprises dopants of a second conductivity type that is an opposite of the first conductivity type at a second atomic concentration that is higher than the first atomic concentration.

19. The method of claim 16, further comprising:
forming a backside stopper layer over the carrier substrate, wherein the source-side spacer layer is formed over the backside stopper layer;
forming an annular recess cavity around the memory opening at a level of the backside stopper layer;
forming an annular semiconductor ring in the annular recess cavity; and
performing a selective semiconductor deposition process that grows a semiconductor material from a physically exposed surface of the annular semiconductor ring, wherein the semiconductor source cap structure comprises a portion of the semiconductor material.

20. The method of claim 19, wherein:
the carrier substrate is removed employing a planarization process or an etch process that employs the backside stopper layer as a stopping layer;
the method further comprises removing a physically exposed portion of the memory film and the backside stopper layer; and
the source layer is formed on a bottom surface of the source-side spacer layer and on an exposed cylindrical sidewall of a remaining portion of the memory film after removal of the physically exposed portion of the memory film.
